(19) United States
(12) Patent Application Publication
(10) Pub. No.: US 2022/0276957 A1
(43) Pub. Date: Sep. 1, 2022

(54) CONTROLLER, SEMICONDUCTOR STORAGE DEVICE, AND A WEAR-LEVELING PROCESSING METHOD IN THE DEVICE

(71) Applicant: Sony Semiconductor Solutions Corporation, Kanagawa (JP)

(72) Inventor: Haruhiko Terada, Kanagawa (JP)

(21) Appl. No.: 17/627,984

(22) PCT Filed: Jul. 8, 2020
(86) PCT No.: PCT/JP2020/026700

§ 371 Date: Jan. 18, 2022

(30) Foreign Application Priority Data
Aug. 19, 2019 (JP) 2019-149894

(51) Int. Cl. G06F 12/02; G06F 12/1009; G06F 3/06

(52) U.S. Cl. CPC G06F 12/0246; G06F 12/1009; G06F 3/0616; G06F 3/0658; G06F 3/0679; G06F 2212/7211

(57) ABSTRACT

An object is to reduce write failures by eliminating localization of wearout of cells in a memory in accordance with characteristics of a Xp-ReRAM and maximize a lifetime of the memory. The present technology includes a controller that controls an operation of a semiconductor storage device including a writable nonvolatile memory. The controller includes: an access control unit that controls access to data storage regions based on some of a plurality of memory cells in the nonvolatile memory in accordance with an address translation table holding mapping information that indicates a correspondence between physical addresses specifying the data storage regions and logical addresses; and a wear-leveling processor that performs a wear-leveling process that levels wearout of the plurality of memory cells that is caused by the access. The wear-leveling processor performing the wear-leveling process with a predetermined probability at each time of the access.

### TECHNICAL FIELD

The present technology relates to a controller, a semiconductor storage device, and a wear-leveling processing method in the device.

### BACKGROUND ART

A rewritable semiconductor storage device having nonvolatility has been known, and recently, as a semiconductor storage device having a storage capacity exceeding a storage capacity of a DRAM and high speed comparable to speed of the DRAM while having nonvolatility, a resistive RAM (ReRAM (Resistive RAM)) has attracted attention. The ReRAM records information according to the state of a resistance value of a cell that changes by application of a voltage. In particular, a Xp-ReRAM (cross-point ReRAM) has a cell structure in which a variable resistor element (VR: Variable Resistor) functioning as a storage element and a selector element (SE: Selector Element) having bidirectional diode characteristics are coupled in series at an intersection of a word line and a bit line.

Such a rewritable semiconductor storage device is known to rarely cause a predetermined operation failure during its operation. A technology for handling such an operation failure is therefore proposed.

For example, the following PTL 1 discloses a technology in which if the number of recording cycles for a data write destination logical block address in a logical block counter is relatively large, a memory controller allocates, to the data write destination logical block address, a physical block address with the number of erase cycles that is relatively small in a physical block counter, among spare blocks that are physical blocks to which logical block addresses are not allocated in a logical-physical conversion table, thereby averaging the number of erase cycles for physical blocks.

In addition, the following PTL 2 discloses a technology in which in a Xp-ReRAM after the resistance value of a reference cell including a variable resistor element that reversibly changes between a low resistance state LR and a high resistance state HR in accordance with application of an electrical signal is set, for example, to boundary conditions (a worst state) of a state in which each memory cell in a memory cell array holds information, such as an upper limit value (LRmax) of a resistance distribution in a low resistance state or a lower limit value (HRmin) of a resistance distribution in a high resistance state, temporal change of the resistance value of the reference cell is observed, and degradation of an information holding state of the reference cell is detected prior to each memory cell and a refresh operation is performed on the reference cell.

In addition, the following PTL 3 discloses a technology in which in a ReRAM, number-of-write-cycles information, which is the number of write cycles for a nonvolatile memory to which access is made in units of pages which are divided by a page size, is held, whether or not refresh, which is inversion of values of all memory cells included in the pages, is necessary is determined on the basis of the held number-of-write-cycles information, and if the refresh is necessary, the refresh is further performed in addition to writing.

In addition, the following PTL 4 discloses a technology in which in a ReRAM, it is determined whether or not a bit number of a specific value from between binary values (“0” and “1”) is greater than a reference value (e.g., one half) in at least part of input data to a memory cell, which executes rewriting to one of the binary values and rewriting to the other one of the binary values in order in a write process (a writing process), determination data indicating a result of the determination is generated, and in a case where it is determined that the bit number is greater than the reference value, the input data at least part of which is inverted is outputted as write data to the memory cell together with the determination data.

### CITATION LIST

### Patent Literature

PTL 1: Japanese Unexamined Patent Application Publication No. 2016-184402

PTL 2: International Publication No. WO2012/140903

PTL 3: International Publication No. WO2016/067846

PTL 4: Japanese Unexamined Patent Application Publication No. 2013-239142

### SUMMARY OF THE INVENTION

### Problem to be Solved by the Invention

Examples of the operation failure include a write failure in which writing of data to a storage element fails. It is confirmed that the write failure also occurs in a semiconductor storage device including the Xp-ReRAM described above, which causes an influence such as reduction in operation reliability and reduction in use lifetime. Some write failures in the Xp-ReRAM are caused by localization of wearout of cells in a memory due to characteristics of the Xp-ReRAM.

However, the technologies as described in PTLs 1 to 4 do not eliminate localization of wearout of the cells in the memory in consideration of the characteristics of the Xp-ReRAM to achieve reduction in write failures.

Therefore, an object of the present technology is to provide a controller that makes it possible to reduce write failures by eliminating localization of wearout of cells in a memory in accordance with characteristics of a Xp-ReRAM and maximize a lifetime of the memory, a semiconductor storage device, and a wear-leveling processing method in the device.

### Means for Solving the Problem

The technology for solving issues described above is configured by including specific matters of the invention or technical features described below.

An aspect of the present technology is a controller that controls an operation of a semiconductor storage device including a writable nonvolatile memory, the controller including: an access control unit that controls access to data storage regions based on some of a plurality of memory cells in the nonvolatile memory in accordance with an address translation table holding mapping information that indicates a correspondence between physical addresses specifying the data storage regions and logical addresses; and a wear-leveling processor that performs a wear-leveling process that levels wearout of the plurality of memory cells that is caused by the access, the wear-leveling processor performing the wear-leveling process with a predetermined probability at each time of the access.

It is to be noted that, in the present specification and the like, means does not simply mean physical means, and includes a case where the function of the means is implemented by software. In addition, a function of one means may be implemented by two or more physical means, and functions of two or more means may be implemented by one physical means.

In addition, a “system” used herein refers to a logical assembly of a plurality of devices (or function modules for implementing a particular function), and does not particularly specify whether or not the devices or function modules are in a single housing.

Other technical features, objects, operations and effects, or advantages of the present technology will become apparent from the following embodiments described with reference to the accompanying drawings. In addition, the effects described herein are merely illustrative and non-limiting, and other effects may be provided.

### BRIEF DESCRIPTION OF THE DRAWINGS

FIG. 1 is a diagram illustrating an example of a schematic configuration of a semiconductor storage device according to an embodiment of the present technology.

FIG. 2 is a diagram illustrating a schematic structure of a die in the semiconductor storage device according to the embodiment of the present technology.

FIG. 3 is a diagram illustrating an example of a schematic structure of a bank in the semiconductor storage device according to the embodiment of the present technology.

FIG. 4 is a diagram illustrating a configuration of a memory cell array in the semiconductor storage device according to the embodiment of the present technology.

FIG. 5 is a diagram illustrating an example of a structure of sector data in the semiconductor storage device according to the embodiment of the present technology.

FIG. 6 is a block diagram illustrating an example of a functional configuration of the semiconductor storage device according to the embodiment of the present technology.

FIG. 7 is a diagram illustrating an example of a data structure of mapping information in the semiconductor storage device according to the embodiment of the present technology.

FIG. 8A is a diagram that describes a correspondence example of logical sectors and physical sectors based on sector group management information in the embodiment of the present technology.

FIG. 8B is a diagram that describes a correspondence example of the logical sectors and the physical sectors based on the sector group management information in the embodiment of the present technology.

FIG. 9 is a diagram illustrating information space of a nonvolatile memory according to the embodiment of the present technology.

FIG. 10A is a flowchart illustrating an example of a data writing process in the semiconductor storage device according to the embodiment of the present technology.

FIG. 10B is a flowchart illustrating an example of the data writing process in the semiconductor storage device according to the embodiment of the present technology.

FIG. 11A is a flowchart illustrating an example of an address remapping process in the semiconductor storage device according to the embodiment of the present technology.

FIG. 11B is a flowchart illustrating an example of an section update process in the address remapping process in the semiconductor storage device according to the embodiment of the present technology.

FIG. 12 is a flowchart illustrating an example of a data readout process in the semiconductor storage device according to the embodiment of the present technology.

FIG. 13 is a diagram illustrating a simulation result of the address remapping process in the semiconductor storage device according to the embodiment of the present technology.

FIG. 14 is a diagram illustrating a verification result of a refresh process in the semiconductor storage device according to the embodiment of the present technology.

### MODES FOR CARRYING OUT THE INVENTION

Hereinafter, embodiments of the present technology are described with reference to the drawings. However, the embodiments described below are only exemplary, and are not intended to exclude the application of various modifications and techniques that are not explicitly disclosed below. The present technology can be variously modified (e.g., combining individual embodiments and the like) and carried out without departing from the gist thereof. In addition, in the following description of the drawings, the same or similar portions are denoted by the same or similar reference numerals. The drawings are schematic, and do not necessarily correspond to actual dimensions, ratios, and the like. Further, there are cases where the drawings include portions that are different from each other in dimensional relationship or ratio.

### First Embodiment

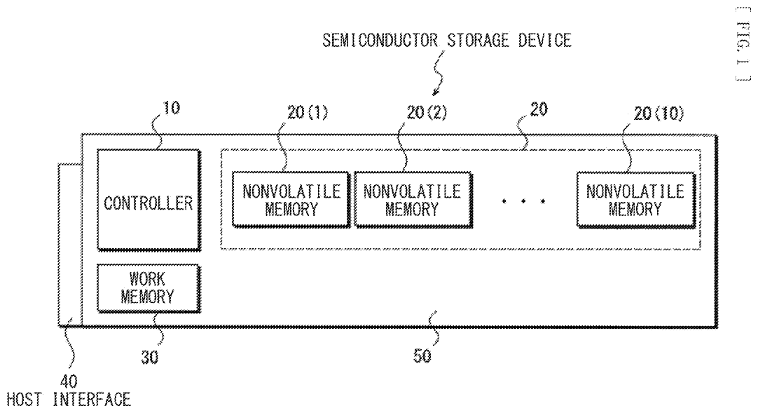

FIG. 1 is diagram illustrating an example of a schematic configuration of a semiconductor storage device 1 according to an embodiment of the present technology (hereinafter abbreviated to the “present embodiment”). As illustrated in the diagram, the semiconductor storage device 1 is configured to include, for example, a controller 10, a plurality to rewritable nonvolatile memories (hereinafter referred to as “nonvolatile memories”) 20, a work memory 30, and a host interface 40, which may be disposed on one board 50, for example.

The controller 10 is a component that totally controls an operation of the semiconductor storage device 1. The controller 10 according to the present technology is configured to be able to perform a process for handling localization of wearout of memory cells MC, as described later.

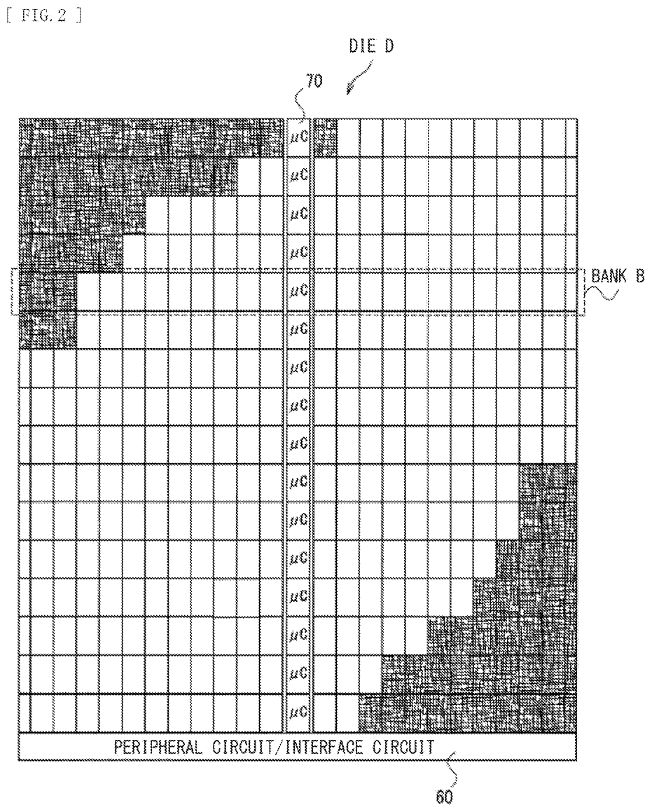

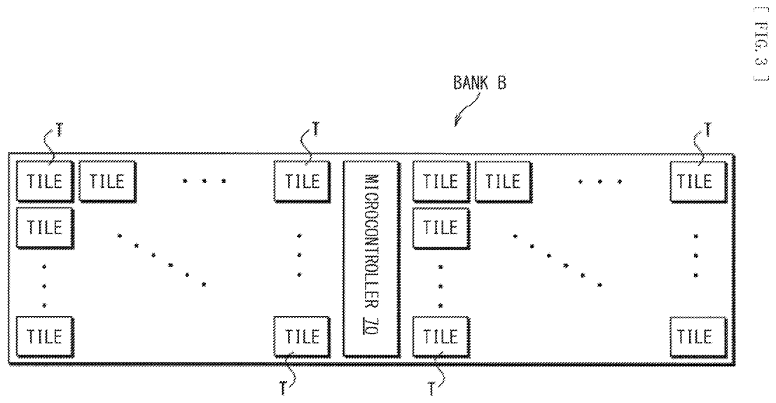

The nonvolatile memory 20 is a component for storing user data received from an unillustrated host and various types of control data, and is provided with ten nonvolatile memory packages 20(1) to 20(10) in this example. A ReRAM is one example of the nonvolatile memory. Examples of the control data include metadata, address management data, error correction data, and the like. One nonvolatile memory package 20 has, for example, a memory capacity of 8 gigabytes×8 dies=64 gigabytes; therefore, the nonvolatile memory 20 that is able to store valid data in eight nonvolatile memory packages out of the ten nonvolatile memory packages achieves a memory capacity of 64 gigabytes×8 packages=512 gigabytes. In addition, as illustrated in FIG. 2, each die D is configured to include, for example, 16 banks B, microcontrollers 70 (represented by “μC” in the diagram) corresponding to the respective banks B, and a peripheral circuit/interface circuit 60. In addition, as illustrated in FIG. 3, each bank B is configured to include tiles T including memory cell arrays (256 memory cell arrays in this example) each having a 1-bit access unit and a microcontroller 70 that controls these tiles T. Each bank B cooperatively operates a group of the tiles T under control by the microcontroller 70 to achieve access to a data block having a predetermined byte size (256 bytes in this example) as a whole.

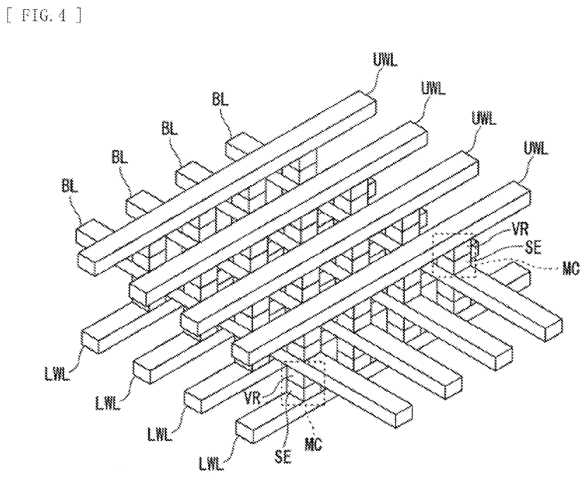

The tile T has, for example, a two-layer memory cell array configuration as illustrated in FIG. 4. A two-layer memory cell array in this example includes a memory cell MC of 1 bit at each of intersections of upper word lines UWL and bit lines BL and intersections of lower word lines LWL and the bit lines BL. The memory cell MC has a series structure of a variable resistor element VR (Variable Resistor) and a selector element SE (Selector Element). The variable resistor element VR records information of 1 bit by high and low states of a resistance value, and the selector element SE has bidirectional diode characteristics. It is to be noted that hereinafter the “memory cell” is also simply referred to as “cell”.

Returning to FIG. 1, the work memory 30 is provided for an increase in speed of the semiconductor storage device 1, wearout reduction, and the like, and is a component that temporarily holds the entirety or a part of management data stored in the nonvolatile memory 20. The work memory 30 includes, for example, a rewritable volatile memory such as a high-speed accessible DRAM. The size of the work memory 30 may be set in accordance with the size of the nonvolatile memory 20.

The host interface 40 is an interface circuit for allowing the semiconductor storage device 1 to perform data communication with an unillustrated host under control by the controller 10. The host interface 40 is configured according to the PCI Express standard, for example.

As described above, in a Xp-ReRAM, a write failure may occur due to localization of wearout of cells. The write failure includes the following failures.

### (1) Write Failure Due to Write Wearout

The variable resistor element VR of the memory cell MC is worn out by repeating setting that changes a resistance value from an HRS (a high resistance state) to an LRS (a low resistance state) or resetting that changes the resistance value from the LRS to the HRS, that is, by writing or rewriting data (bit data). This is called write wearout (Write Endurance Wore-out). Writing or rewriting to the memory cell MC has a limit based on write wearout. In a case where the number of write cycles, which is measured with erasing and writing (setting or resetting) of data as one cycle, for one memory cell MC reaches the endurance number of write cycles (Write Endurance), write wearout reaches a limit, which eventually causes a stuck failure. In the semiconductor storage device 1 according to the present embodiment, the endurance number of write cycles for the memory cell MC is, for example, 1200000 (1.2e6) cycles.

The stuck failure is an error that the resistance value of the variable resistor element VR of the memory cell MC is not changed from the HRS to the LRS or from the LRS to the HRS, thereby causing a write failure. The stuck failure include Stuck-LRS and stuck-HRS (hereinafter collectively also referred to as “stuck-LRS/HRS”). In the stuck-LRS, the variable resistor element VR is stuck to the LRS, and in the stuck-HRS, the variable resistor element VR is stuck to the HRS. Whether the memory cell MC is stuck to the stuck-LRS or the stuck-HRS depends on characteristics of the memory cell MC and the pattern of data to be written, and may be indefinite.

### (2) Write Failure Due to Readout Wearout

The selector element SE of the memory cell MC is worn out by repeating not only writing but also readout. This is called readout wearout (Read Endurance Wore-out). The readout wearout is caused by repeat of readout from the memory cell MC in the LRS. Specifically, in a case where the memory cell MC that is a readout target is in the LRS, a phenomenon (snap) is caused in which a voltage at both ends (a word line and a bit line BL) of the selector element SE in a selection state (an ON state) is deceased to cause a current to abruptly flows between both the ends. Readout wearout is caused by repeat of the snap. Readout of data from the memory cell MC has a limit based on readout wearout, and in a case where the number of readout cycles in the LRS reaches the endurance number of readout cycles (Read Endurance), the readout wearout caused by the snap reaches a limit, which eventually causes a disturb failure. In this example, the endurance number of readout cycles for the memory cell MC is, for example, 6000000 (6.0e6) cycles.

In a case where the disturb failure occurs due to readout wearout, a threshold voltage of the selector element SE becomes lower than normal, which causes a current of a low voltage to flow into the memory cell MC. This also causes a write failure in other memory cells MC on the same word line WL (the upper word line UWL and the lower word line LWL) and the same bit line BL of the memory cell MC in which the disturb failure has occurred.

The disturb failure is a failure specific to the Xp-ReRAM, and unlike the stuck failure, the disturb failure causes a write failure in many normal memory cells MC that share the word line and the bit line. Accordingly, a significant improvement in operation reliability and a use lifetime of the nonvolatile memory 20 are expectable by preventing readout wearout.

### (3) Write Failure Due to Successive Readout

In addition, even if the readout cycles from the memory cell MC in the LRS does not reach the endurance number of readout cycles described above, a write failure may occur due to successive readout (Read-induced Over-SET). The successive readout is an phenomenon in which the number of cycles of successive readout (the number of successive readout cycles) without changing the memory cell MC in the LRS to the HRS reaches the reference number of successive readout cycles (Over-Set Criteria), thereby induces the stuck-LRS. In this example, the reference number of successive readout cycles are, for example, about 10000 (1.04e) cycles. A write failure due to successive readout is caused by both characteristics of the selector element SE and characteristics of the variable resistor element VR, and is a failure specific to the Xp-ReRAM.

Thus, three types of write failures in the present technology are caused by localization of wearout of the memory cell MC (wearout of the variable resistor element VR and the selector element SE) in the nonvolatile memory 20 by repeat of access (writing, rewriting, readout, or the like) to a specific memory cell MC, that is, concentration of access. Accordingly, the controller 10 according to the present technology is configured to be able to perform, as a process for handling the write failures that occur in the nonvolatile memory 20, a wear-leveling process that levels wearout of the respective memory cells MC with a predetermined probability at the time of access to the nonvolatile memory 20. The wear-leveling process is a process that allows access to the memory cells MC in the entire nonvolatile memory 20 to be distributed.

Examples of the wear-leveling process include an address remapping process, a data inversion process, and a refresh process. The address remapping process is a process for averaging the number of write (including rewrite) cycles for the respective memory cells MC in the nonvolatile memory 20 by an address remapping (Address Remapping) technology. In addition, the data inversion process is a process for averaging the number of setting process cycles and the number of resetting process cycles for the respective memory cells MC in the nonvolatile memory 20 by inverting data (write data) to be written to the memory cells MC. In addition, the refresh process is a process that prevents successive readout in the LRS by temporarily changing all the memory cells MC in the LRS among access target memory cells MC in the nonvolatile memory 20. These wear-leveling processes are described in detail later.

In the semiconductor storage device 1 according to the present technology, wearout of the memory cells MC in the entire nonvolatile memory 20 is leveled by these wear-leveling processes to eliminate localization of wearout of the memory cells MC, which makes it possible to prevent the write failures. In addition, the write failures are prevented by the wear-leveling processes, which maximizes the use lifetime of the nonvolatile memory 20.

In the semiconductor storage device 1 according to the present technology, memory access is managed, for example, in units of data blocks such as sections, sectors, and pages. That is, the section is a data block in which a memory capacity (512 gigabytes) of the nonvolatile memory 20 is partitioned and managed in units of 8 kilobytes. The section stores, for example, 32 sectors that are data blocks of 320 bytes (real data has 256 bytes). The sector is a data block that stores sector data of 320 bytes, and is a basic access unit to an unillustrated host. The sector data is divided into 10 pages that are, for example, data blocks of 32 bytes, and is written to and stored in the nonvolatile memory 20 through different channels. The page is an access unit to one bank in one die D of the nonvolatile memory 20, and each of bits in each page corresponds to each of bits (the memory cells MC) of the tiles T in each bank B.

The sector in the semiconductor storage device 1 according to the present technology is managed while being divided into a physical sector corresponding to a data storage region based on a plurality of memory cells MC in the nonvolatile memory 20 and a logical sector corresponding to a virtual data storage region mapped (corresponding to) the physical sector for access control in the controller 10. In addition, a section that stores 32 physical sectors is a physical section, and a section that stores 32 logical sectors mapped to the physical sectors is a logical section. In addition, as described in detail later, in the semiconductor storage device 1, physical addresses (physical section addresses and physical sector addresses that are to be described later) that specify physical sections and physical sectors and logical addresses (logical section addresses and logical sector addresses that are to be described later) that specify logical sections and logical sectors are mapped in units of sections. That is, the sections in the semiconductor storage device 1 are access units used for mapping between the logical addresses and the physical addresses. This makes it possible for the controller 10 to access the physical sectors that are data storage regions in memory access in the semiconductor storage device 1.

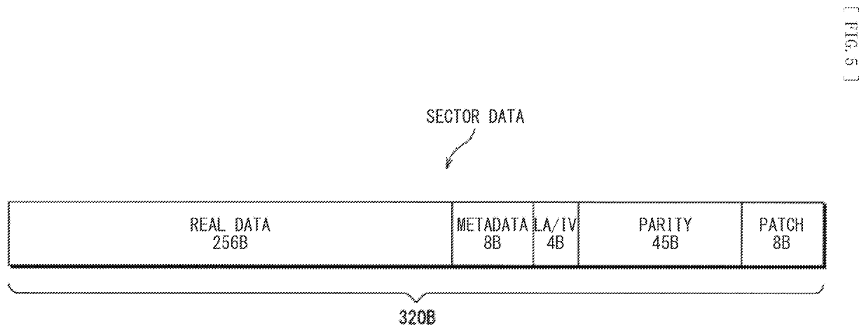

FIG. 5 is a diagram illustrating an example of a structure of sector data in the semiconductor storage device 1 according to the embodiment of the present technology. That is, as illustrated in the diagram, the sector data is data of 320 bytes including, for example, real data of 256 bytes, metadata of 8 bytes, a logic section address-inversion flag (hereinafter referred to as “LA/IV”) of 4 bytes, an ECC parity (hereinafter referred to as “parity”) of 45 bytes, and a patch of 7 bytes. The metadata is secondary data for managing the real data, and includes, for example, address information, a CRC checksum, a version number, a time stamp, and the like. The real data and the metadata correspond to user data received from the unillustrated host. The parity is parity data generated using, for example, the real data, the metadata, and the LA/IV as a payload. The patch stores a correct value that is to be originally recorded on the memory cells MC in which the stuck failure and the disturb failure have occurred in the sector. It is to be noted that the sector data is also an access unit between the unillustrated host and the semiconductor storage device 1. The sector data of 320 bytes is divided into, for example, 10 channels and stored on the semiconductor storage device 1. The LA/IV, the parity, and the patch are data to be added to the user data by the controller 10.

Here, generally, a semiconductor storage device is desired by users to achieve an improvement in performance and reduction in bit cost in relatively small access units. In contrast, in terms of error correction, an improvement in error correction capability is expected by generating a parity in relatively large access units. In view of these circumstances, in the semiconductor storage device 1 in this example, a real data size is 256 bytes. It is to be noted that the size of real data in sector data may be designed appropriately in accordance with desired conditions (such as performance accuracy or error correction).

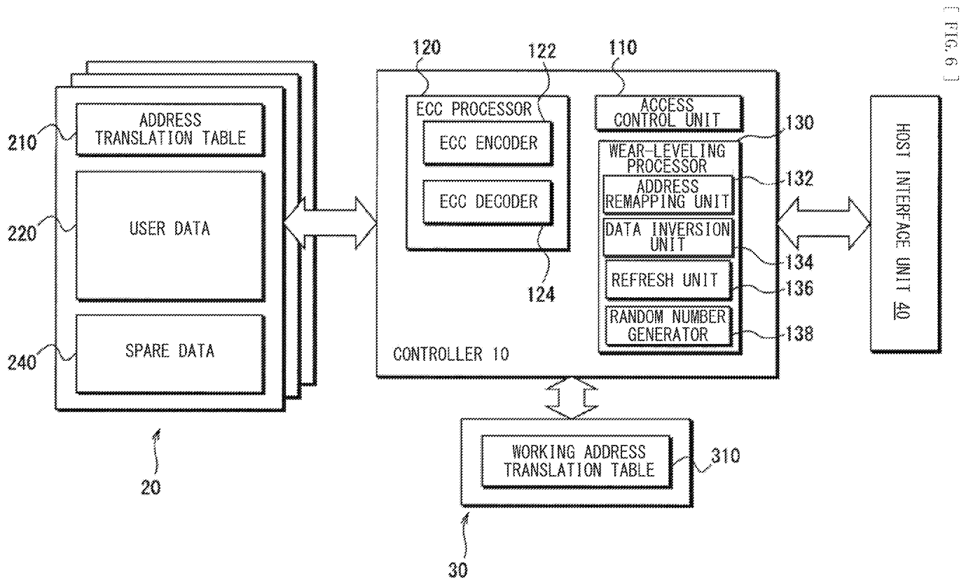

FIG. 6 is a block diagram illustrating an example of a functional configuration of the semiconductor storage device 1 according to the embodiment of the present technology. The diagram functionally illustrates the configuration of the semiconductor storage device 1 illustrated in FIG. 1.

In the diagram, the controller 10 totally controls the operation of the semiconductor storage device 1 including the nonvolatile memory 20. For example, upon reception of an access command from the unillustrated host via the host interface unit 40, the controller 10 performs control to access the nonvolatile memory 20 by an access control unit 110 to be described later in accordance with the access command, and issue or transmit a result of such access to the host.

In this example, the controller 10 performs various processes (the wear-leveling processes) for eliminating localization of wearout of the memory cells MC caused by access to the nonvolatile memory 20 to reduce occurrence of write failures. The controller 10 may be configured to include the access control unit 110, a wear-leveling processor 130, and an ECC processor 120, as illustrated in the diagram.

The access control unit 110 controls access to the physical sectors in accordance with an address translation table that holds mapping information indicating a correspondence between the physical addresses that specify the physical sectors in the nonvolatile memory 20 and the logical addresses. Here, the physical sector is one form of a data storage region based on some memory cells MC (the memory cells MC for 320 bytes (320 memory cells MC) in this example) of a plurality of memory cells MC in the nonvolatile memory 20.

The access control unit 110 controls access to the nonvolatile memory 20 on the basis of an access command received from the host by the controller 10. The access command is received together with the user data (the real data and the metadata) of the sector data described above (see FIG. 5) by the controller 10. The access command includes at least a write access command for requesting writing data to a sector (the physical sector) of the nonvolatile memory 20 and a readout access command for requesting data readout from a physical sector. The access control unit 110 performs write access in which data is written to the physical sector upon reception of the write access command. In addition, the access control unit 110 performs readout access in which data is read out from the physical sector upon reception of the readout access command.

The access control unit 110 performs an address translation process that translates a logical address received from the unillustrated host into a physical address on the nonvolatile memory 20 for access to a sector (a physical sector) of the nonvolatile memory 20. Specifically, the logical address is stored as address information in the metadata of the user data (the real data and the metadata (see FIG. 5)) transmitted together with the access command from the unillustrated host. The access control unit 110 refers to mapping information held by a working address translation table 310 on the work memory 30 to be described later on the basis of the received logical address, and performs the address translation process. In the address translation process, a logical address (a logical section address in this example) of the semiconductor storage device 1 corresponding to the logical address received from the host is translated into a physical address on the nonvolatile memory 20. It is to be noted that the controller 10 may include an address translation unit that executes the address translation process, as a functional configuration independent of the access control unit 110.

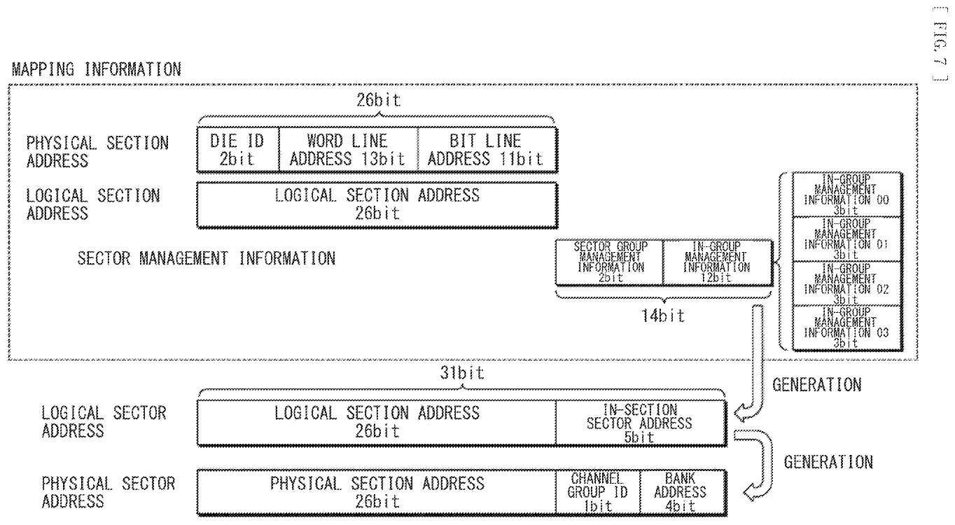

FIG. 7 is a diagram illustrating an example of a data structure of addresses included in mapping information used for the address translation process. The mapping information includes physical section addresses, logical section addresses mapped to (corresponding to) the physical section addresses, and sector management information accompanying the logical section addresses, and is stored in the working address translation table 310. In the present embodiment, the mapping information is held in the working address translation table 310 in units of sections. That is, the mapping information is held for each physical section storing 32 physical sectors in the working address translation table 310. As described in detail later, in the present embodiment, mapping between the physical section addresses and the logical section addresses in the mapping information is variable.

The physical section address is an address for specifying a physical section that stores physical sectors that are data storage regions on the nonvolatile memory 20, and includes, for example, a die ID of 2 bits, a word line address of 13 bits, and a bit line address of 11 bits, for a total of 26 bits. The die ID is information that identifies a die D in each of the nonvolatile memories 20(1) to 20(10). The word line address is an address that specifies each of the upper word lines UWL and the lower word lines LWL in each tile T in each bank B in the die D, and the bit line address is an address specifies each of the bit lines BL in each tile T. In the semiconductor storage device 1 according to the present embodiment, each tile T includes 8192 (2\hat{ }13) word lines (4096 upper word lines UWL and 4096 lower word lines LWL) and 2048 (2\hat{ }11) bit lines BL. The physical section address specifies a die D in each nonvolatile memory 20 and memory cells MC in the banks D of the die D.

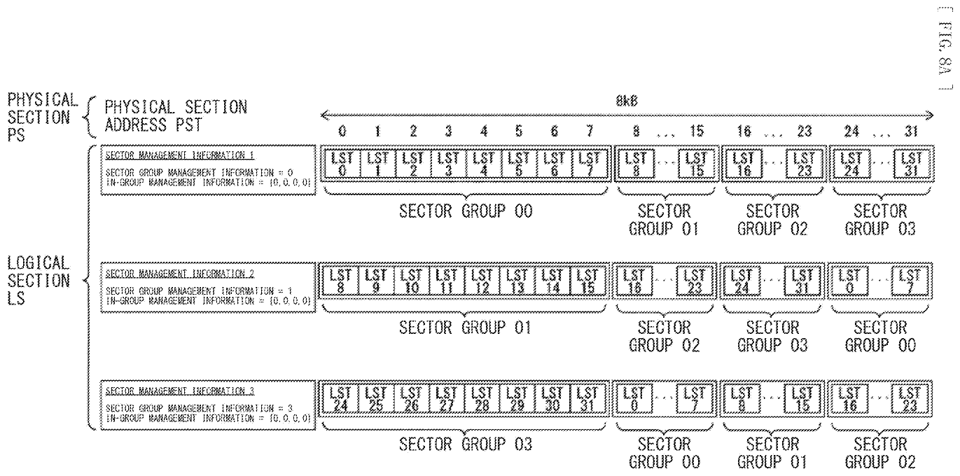

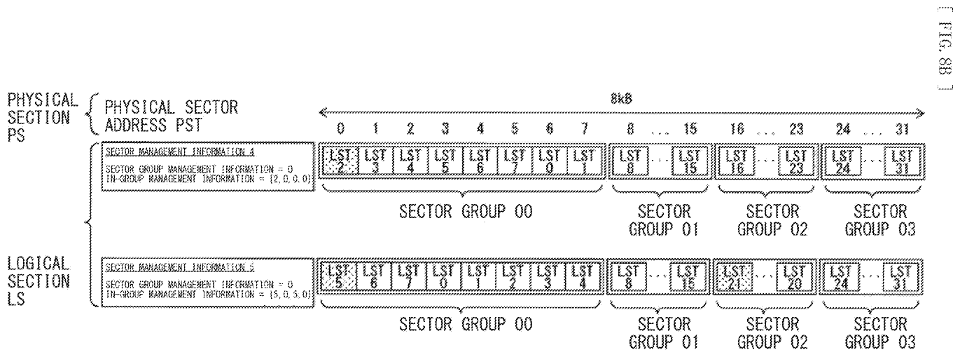

In the semiconductor storage device 1, the logical section that is a data block used for access control in the access control unit 110 is mapped to the physical section (see FIGS. 8A and 8B to be described later). The logical section address is a bit string of 26 bits similar to the physical section address, and is an address for specifying the logical section mapped to the physical section. The logical section address is mapped to any physical section address by the controller 10.

The sector management information includes sector group management information of 2 bits and in-group management information of 12 bits, for a total of 14 bits, and is information that manages mapping between 32 sectors (logical sectors) in the logical section and 32 sectors (physical sectors) in the physical section. In the present technology, in view of compatibility between leveling of wearout of the memory cells MC and prevention of bloating of the mapping information, in the address translation table (an address translation table 210 to be described later and the working address translation table 310), 32 logical sectors in the logical section is partitioned into four sector groups each including eight logical sectors, and mapping between the logical sectors and the physical sectors is managed in units of the sector groups. It is to be noted that in this example, the sector groups are groups used for management of the logical sectors in the mapping information, and are not data blocks in the semiconductor storage device 1. The sector group management information of 2 bits is information that manages mapping between the logical sectors and the physical sectors in units of sector groups (in units of eight sectors). Furthermore, in the address translation table (the address translation table 210 and the working address translation table 310), one-on-one mapping between each of eight logical sectors in each sector group and each of eight physical sectors mapped to each sector group is managed by in-group management information of 3 bits. As illustrated in FIG. 8 to be described later, the in-group management information of 12 bits includes in-group management information of 3 bits for each of four sector groups (groups 00 to 03 in this example).

It is possible to specify logical address information of 31 bits (the logical section address and sector management information for one sector group) by a logical address received from the host. Accordingly, upon reception of the access command, in the address translation process, the access control unit 110 refers to the address translation table (e.g., the working address translation table 310), and obtains a logical section address (an access destination logical section address) from the mapping information on the basis of a received logical address. The access control unit 110 generates a logical sector address for uniquely specifying a logical sector in the logical section from the obtained access destination logical section address. The logical sector address includes a logical section address of 26 bits corresponding to the received logical address and an in-section sector address of 5 bits. Here, the in-section sector address is generated from sector management information of 2 bit in sector management information and in-group management information of 3 bits corresponding to one sector group among four sector groups. The access control unit 110 specifies one sector group from four sector groups corresponding to the obtained access destination logical section address on the basis of the received logical address.

After generation of the logical sector address, the access control unit 110 translates the generated logical sector address into a physical sector address. The physical sector address is an address that specifies a physical sector, and is used for discriminating among 32 physical sectors stored in the physical section.

The physical sector address includes a physical section address of 26 bits corresponding to the obtained logical section address, a channel group ID of 1 bit, and a bank address of 4 bits, for a total of 31 bits. The channel group ID and the bank address are generated by translating the in-section sector address of 5 bit in the logical sector address. The channel ID is information that specifies a channel that couples the controller 10 and each of the nonvolatile memories 20(1) to 20(10) to each other. In the present embodiment, the controller 10 and ten packages of the nonvolatile memories 20 are coupled to each other by 10 channels×2 systems, for a total of 20 channels. Specifically, each nonvolatile memory 20 is coupled to the controller 10 by two channels of different systems, and eight dies D in each nonvolatile memory 20 are coupled to channels of different systems by four dies. In addition, the bank address is an address that specifies each of 16 banks B of each die D, and different addresses are allocated to the banks B in each die D.

Thus, the semiconductor storage device 1 according to the present technology is able to translate the logical address received from the host into a physical address (a physical sector address in this example) on the basis of the mapping information held in the address translation table (the address translation table 210 and the working address translation table 310).

The access control unit 110 outputs, to the wear-leveling processor 130, the mapping information corresponding to an access target physical sector including the physical sector address obtained in the address translation process. This makes it possible for the wear-leveling processor 130 to perform a wear-leveling process for eliminating localization of wearout of the memory cells MC belonging to the access target physical sector.

The wear-leveling processor 130 performs a wear-leveling process that levels wearout of the memory cells MC in the nonvolatile memory 20 caused by access (write access or readout access). In the controller 10 according to the present embodiment, the wear-leveling processor 130 performs the wear-leveling process on the memory cells MC belonging to the access target physical sector, thereby eliminating localization of wearout of the memory cells MC in the entire nonvolatile memory 20. This makes it possible for the controller 10 to level wearout of the memory cells MC in the nonvolatile memory 20 and reduce occurrence of write failures.

In addition, the wear-leveling processor 130 according to the present embodiment performs the wear-leveling process with a predetermined probability for each access to the physical sector by the access control unit 110. That is, the wear-leveling processor 130 stochastically executes the wear-leveling process without measuring (counting) the number of data write cycles to the memory cells MC belonging to the physical sector, the number of data erase cycles in the memory cells MC, the number of data readout cycles from the memory cells MC, and the like.

Generally, a semiconductor storage device including a nonvolatile memory is desired to maintain data reliability even at the time of sudden power shutdown. Accordingly, in a counter-based algorithm based on various types of numbers of cycles as described above, a need arises to sequentially store counter information in the nonvolatile memory. However, frequent recording of the counter information to the nonvolatile memory may decrease access speed to the host, and a decrease in the access speed affects operation performance of the semiconductor storage device more with an increase in access frequency (iops: the number of input/output operations per second) in semiconductor storage device. Here, in the Xp-ReRAM, access frequency exceeding 10 mega iops is claimed. Therefore, recording cost of the counter information that does not become apparent in an existing flash memory-based semiconductor storage device (access frequency is about 100 kilo iops or less) becomes pronounced. Accordingly, the controller 10 according to the present technology stochastically executes the wear-leveling process as described above, not on a counter basis. This makes it possible for the controller 10 to perform the wear-leveling process while maintaining desired operation performance without decreasing the access speed in the semiconductor storage device 1.

The wear-leveling processor 130 may be configured to include, for example, an address remapping unit 132 that performs the address remapping process as the wear-leveling process, a data inversion unit 134 that performs the data inversion process, a refresh unit 136 that performs the refresh process, and a random number generator 138 that generates a random number within a predetermined numerical range. The address remapping unit 132 is one form of a table update unit, the data inversion unit 134 is one form of a data inversion processor, and the refresh unit 136 is one form of a resistance state changing unit.

The address remapping unit 132 performs the address remapping process for averaging the number of rewrite cycles (write cycles) for the respective memory cells MC in the nonvolatile memory 20 by the address remapping (Address Remapping) technology. The address remapping process is one example of a table update process. Specifically, as the address remapping process, the address remapping unit 132 updates mapping information in the working address translation table 310 with a predetermined address remapping probability for each access to the physical sector by the access control unit 110. The predetermined address remapping probability is one example of a first probability. That is, the address remapping process in the present embodiment is stochastically executed for each access to the nonvolatile memory 20.

In the present embodiment, the address remapping unit 132 may perform, as the address remapping process, a section update process that updates mapping information in the working address translation table 310 in units of sections, and a sector group update process that updates the mapping information in units of the sector groups described above.

In the section update process, the address remapping unit 132 updates the mapping information with the predetermined address remapping probability for each access (write access and readout access) to the physical sector by the access control unit 110, and updates the physical section address to be mapped to the access destination logical section address. Accordingly, mapping between the access target physical sector and the logical sector is updated for each section. That is, the address remapping unit 132 is able to perform update of the mapping information by the address remapping process for each section (physical section) where the access target physical sector is stored.

In addition, in the sector group update process, the address remapping unit 132 updates the mapping information with the predetermined address remapping probability for each access (write access and readout access) to the physical sector by the access control unit 110, and updates sector management information (see FIG. 7) accompanying the access destination logical section address. The sector group update process includes a first group update process that updates sector group management information in mapping information of the access target physical sector, and a second group update process that updates in-group management information in the mapping information of the access target physical sector.

Here, description is given of the sector group management information and the in-group management information in the sector management information together with mapping between the physical sectors and the logical sectors in the section with reference to FIGS. 8A and 8B.

A first stage in FIG. 8A illustrates the order of 32 physical sectors stored in a physical section PS that is a data block equivalent to 8 kilobytes. In this example, the physical sectors stored in the physical section PS are specified by physical sector addresses PST0 to PST31. In the physical section PS, 32 physical sectors are stored in ascending order of the physical sector addresses, for example. In the first stage in FIG. 8A, with a physical sector of the physical sector address PST0 in the lead, 32 sectors up to a physical sector of the physical sector address PST31 are arranged in this order. In the present embodiment, allocation of the physical sectors in the physical section is fixed, and the order of the physical sectors in the physical section is also fixed. Accordingly, for example, all 32 physical sectors in the physical section PS correspond to the same logical section (a logical section LS in this example).

In addition, second to fourth stages in FIG. 8A illustrate the order of 32 logical sectors in the logical section LS mapped to the physical section PS. In this example, the logical sectors stored in the logical section LS are specified by logical sector addresses LST0 to LST31. As described above, sector management information is partitioned into four sector groups each including 8 logical sectors, and mapping between the logical sectors and the physical sectors is managed in units of the sector groups. The second to fourth stages in FIG. 8A illustrate 32 logical sectors in the logical section LS that are divided into four sector groups (sector groups 00 to 03) each including eight logical sectors for ease of understanding.

In this example, the sector group 00 includes logical sectors corresponding to logical sector addresses (logical sector addresses LST0 to LST7) up to a top eighth logical sector address in the logical section LS. The sector group 01 includes logical sectors corresponding to top ninth to 16th logical sector addresses (logical sector addresses LST8 to LST15) in the logical section LS. The sector group 02 includes logical sectors corresponding to top 17th to 24th logical sector addresses (logical sector addresses LST16 to LST23) in the logical section LS. The sector group 03 includes logical sectors corresponding to top 25th to 32nd logical sector addresses (logical sector addresses LST24 to LST31) in the logical section LS. In addition, allocation of the logical sectors in the sector groups is fixed.

In addition, in the present embodiment, allocation of the logical sectors in the logical section is fixed as with the physical sectors, and allocation of the logical sectors in each of the sector groups is also fixed. In contrast, the order of the logical sectors in the logical section is variable for each sector group or for each logical sector in each of the sector groups. In the present embodiment, sector management information in the mapping information indicates the shift number (order) for the order (variable) of the logical sectors in each sector group with respect to the order (fixed) of the physical sectors, which enables mapping between the physical sectors and the logical sectors in units of sector groups.

In this example, sector management information 1 illustrated on left side of the second stage in FIG. 8A include sector group management information=“0” and in-group management information=“0, 0, 0, 0”. The sector group management information and the in-group management information are actually bit data, but are replaced and illustrated by decimal numbers in FIGS. 8A and 8B for ease of understanding. Each data (a numerical value) in the sector group management information and the in-group management information indicates the shift number related to the order of logical sectors. For example, the shift number being “0” indicates that the order of the logical sectors is not shifted with respect to the order of the physical sectors. Specifically, the sector group management information=“0” indicates that the order of the sector groups 00 to 03 in units of sector groups is not shifted with respect to the order of the physical sectors.

In addition, the in-group management information=“0, 0, 0, 0” indicates that arrangement of any logical sectors in the sector groups 00 to 03 is not shifted with respect to the order of the physical sectors. In FIGS. 8A and 8B, for ease of understanding, the in-group management information corresponding to the sector groups 00 to 03 is comma delimited. Four pieces of data of the in-group management information indicate the shift numbers for the sector groups 00 to 03 in this order. The in-group management information is actually a bit string of 12 bits including successive pieces of data of 3 bits corresponding to the sector groups 00 to 03. In the in-group management information of 12 bits, 3 bits from its head corresponds to the sector group 00, and every following 3 bits correspond to each of the sector groups 01 to 03. The in-group management information indicates the shift number for eight logical sectors in each of the sector groups with 3 bits for each sector group.

Thus, the sector management information 1 including the sector group management information=“0” and the in-group management information=“0, 0, 0, 0” indicates that the order of the physical sectors in the physical section PS and the order of the logical sectors in the logical section LS match each other. A state in which the orders match each other is referred to as a shift reference state.

In the third stage in FIG. 8A, sector management information 2 includes the sector group management information=“1” and the in-group management information=“0, 0, 0, 0”. The sector group management information=“1” indicates a one-shift state in which the order of the logical sectors, specifically the order of the sector groups 00 to 03 with respect to the shift reference state is shifted by one in one direction (in a leading direction of logical sector addresses in this example). In this example, in the one-shift state of the sector group management information, the order of the sector groups in the logical section LS is cyclically shifted in order of the sector groups 01, 02, 03, and 00. Thus, the sector group management information indicates the shift number for four sector groups with respect to the shift reference state. It is to be noted that in the sector management information 2, the in-group management information is “0, 0, 0, 0”; therefore, the order of the logical sectors in each of the sector groups is not changed from the shift reference state. The same applies to sector management information 3.

The order of the logical sectors in the sector groups being in the one-shift state with respect to the shift reference state namely indicates that the order of the logical sectors is in the one-shift state in group units with respect to the fixed order of the physical sectors. Accordingly, in a case where the order of the sector groups is in the one-shift state, for example, the logical sector addresses LST8 to LST15 that specify the logical sectors in the sector group 01 are mapped to the physical sector addresses PST0 to PST7 in this order, the logical sector addresses LST16 to LST23 that specify the logical sectors in the sector group 02 are mapped to the physical sector addresses PST8 to PST15 in this order, the logical sector addresses LST24 to LST32 that specify the logical sectors in the sector group 03 are mapped to the physical sector addresses PST16 to PST23 in this order, and the logical sector addresses LST0 to LST7 that specify the logical sectors in the sector group 00 are mapped to the physical sector addresses PST24 to PST31 in this order.

In addition, although not illustrated, the sector group management information=“2” indicates a two-shift state in which the order of the sector groups 00 to 03 with respect to the shift reference state is shifted by two in the leading direction of logical sector addresses. In this example, in the two-shift state of the sector groups, the order of the sector groups in the logical section LS is cyclically shifted in order of the sector groups 02, 03, 00, and 01.

In addition, in the fourth stage in FIG. 8A, the sector management information 3 includes the sector group management information=“3” and the in-group management information=“0, 0, 0, 0”. The sector group management information=“3” indicates a one-shift state in which the order of the sector groups 00 to 03 with respect to the shift reference state is shifted by three in the leading direction of logical sector addresses. In this example, in the three-shift state of the sector groups, the order of the sector groups in the logical section LS is cyclically shifted in order of the sector groups 03, 00, 01, and 02.

Thus, in the present embodiment, the sector group management information indicates the order (the shift number) of the logical sectors in the logical section for each sector group. As described above, in the sector group management information, it is possible to specify mapping between the physical sectors and the logical sectors in units of the sector groups by the sector group management information (2 bits) that indicates the shift number of the order of the logical sectors in unis of the sector groups with respect to the order of the physical sectors.

That is, the address remapping unit 132 updates the sector group management information by the first group update process, thereby making it possible to perform update of the mapping information for every several physical sectors in the physical section. Here, several physical sectors in the physical section corresponds to eight physical sectors corresponding to logical sectors in the sector group. That is, in the first group update process, the order of the logical sectors in the logical section, that is, mapping between the physical sectors and the logical sectors is updated in units of sector groups (in units of eight sectors). In addition, the shift number of the order in the sector group management information is always based on the shift reference state. Accordingly, for example, in a case where the sector group management information is updated from “0” to “3”, and in a case where the sector group management information is updated from “1” to “3”, the order of the logical sectors is similarly in the three-shift state (see the fourth stage in FIG. 8A).

A first stage in FIG. 8B illustrates the order of 32 physical sectors stored in the physical section PS similarly to FIG. 8A. Sector management information 4 illustrated on left side of a second stage in FIG. 8B includes the sector group management information=“0” and the in-group management information=“2, 0, 0, 0”. The in-group management information=“2, 0, 0, 0” indicates that the order of the logical sectors in the sector groups is in the two-shift state only in the sector group 00 and is in the shift reference state (is not shifted) in the other sector groups 01 to 03. Accordingly, the order of the logical sectors in the sector group 00 is in the two-shift state in which the order of the logical sectors are shifted by two in the leading direction of logical sector addresses with respect to the shift reference state (see the second stage in FIG. 8A). Specifically, in the two-shift state, the order of the logical sectors in the sector group 00 is cyclically shifted in order of the logical sector addresses LST2 to LST7, LST0, and LST1.

It is to be noted that in the sector management information 4, the sector group management information is “0”. That is, mapping between the physical sectors and the logical sectors in units of the sector groups remains in the shift reference state. Accordingly, in this example, in the sector management information 4, mapping between the logical sectors and the physical sectors is updated only for eight physical sectors of the physical sector addresses PST0 to PST7 mapped to the sector group 00. Specifically, according to the sector management information 4, for example, the logical sector addresses LST2 to LST7, LST0, and LST1 that specify the logical sectors in the sector group 00 are respectively mapped to the physical sectors specified by the physical sector addresses PST0 to PST7 illustrated in the first stage in FIG. 8B in this order.

In addition, sector management information 5 illustrated on left side of a third stage in FIG. 8B includes the sector group management information=“0” and the in-group management information=“5, 0, 5, 0”. This indicates that the order of the logical sectors in the sector groups 00 and 02 is in a five-shift state and the order of the logical sectors in the other sector groups 01 and 03 remains in the shift reference state (is not shifted). Accordingly, the order of the logical sectors in the sector group 00 is in the five-shift state in which the order of the logical sectors is shifted by five in the leading direction of logical sector addresses with respect to the shift reference state (see the second stage in FIG. 8A). Specifically, the order of the logical sectors in the sector group 00 is cyclically shifted in order of the logical sector addresses LST5 to LST7 and LST0 to LST4. In addition, the order of the logical sectors in the sector group 02 is similarly in the five-shift state. Accordingly, the order of the logical sectors in the sector group 02 is similarly cyclically shifted in order of the logical sector addresses LST21 to LST23 and LST16 to LST20.

It is to be noted that in the management information 5, the sector group management information is “0” similarly to the management information 4. That is, the order of the sector groups 00 to 03 remains in the shift reference state. Accordingly, mapping is updated between the logical sectors in the sector group 00 and eight physical sectors of the physical sector addresses PST0 to PST7 mapped to the sector group 00 and between the logical sectors in the sector group 02 and eight physical sectors of the physical sector addresses PST16 to PST23 mapped to the sector group 02. Specifically, eight logical sectors specified by the logical sector addresses LST5 to LST7 and LST0 to LST4 in the sector group 00 are respectively mapped to the physical sectors specified by the physical sector addresses 00 to 07 illustrated in the first stage in FIG. 8B in this order. In addition, eight logical sectors specified by the logical sector addresses LST21 to LST23 and LST16 to LST20 in the sector group 02 are respectively mapped to the physical sectors specified by the physical sector addresses PST16 to PST23 illustrated in the first stage in FIG. 8B in this order.

Thus, in the present embodiment, the in-group management information indicates a cycle state (the shift number) of the logical sectors in the sector group. As described above, the in-group management information manages one-on-one mapping between each of eight logical sectors in each sector group and each of eight physical sectors mapped to each sector group by the in-group management information of every 3 bits.

It is to be noted that in the present technology, the number of sector groups is not limited to four, and may be equal to or less than four or equal to or more than four as long as the same number of logical sectors is included in each of the sector groups. The sector group management information indicating the shift number for each sector group may be set within a first numerical range with the number of sector groups (n sector groups)−1 as a maximum value. However, in a case where the numerical range of the sector group management information increases, it is necessary to increase the number of bits of the sector group management information. Accordingly, in view of suppression of bloating of the mapping information, it is sufficient if the number of sectors is four or less. In addition, the number of the logical sectors in each sector group is also changed in accordance with the number of sector groups. The in-group management information indicating the shift number for the logical sectors in the sector group may be set within a second numerical range with the number of logical sectors (m logical sectors)−1 as a maximum value.

The address remapping unit 132 updates the in-group management information by the second group update process, thereby making it possible to perform update of the mapping information on each of several physical sectors (eight physical sectors mapped to the sector group) in the physical section. That is, in the second group update process, the order of the logical sectors in the sector group is updated. In addition, the shift number of the order in the in-group management information is always based on the shift reference state. Accordingly, in a case where one piece of in-group management information (e.g., in-group management information for the sector group 00) is updated from “0” to “2”, and in a case where the one piece of in-group management information is updated from “1” to “2”, the order of the logical sectors in sectors is similarly in the two-shift state (see the second stage in FIG. 8B).

In the present embodiment, the address remapping unit 132 updates a combination (sector management information) of the sector group management information and the in-group management information, which makes it possible to control the order of the logical sectors in units of sector groups and the order of the logical sectors in each of the sector groups independently of each other.

In a case where the management information and the in-group management information in the sector management information (see FIG. 7) are updated by the sector group update process (the first group update process and the second group update process), the in-section sector address generated by the sector group management information and the in-group management information is updated. That is, the physical sector address obtained by translating the logical sector address based on the access destination logical section address.

In the present embodiment, the address remapping unit 132 may perform the sector group update process (the first group update process and the second group update process) simultaneously with the section update process. That is, the address remapping unit 132 may also perform update of mapping information in units of sector groups and for each of the logical sectors in the sector group at the time of update of mapping information in units of sections. Accordingly, the address remapping unit 132 in the controller 10 according to the present embodiment is configured to be able to collectively execute a plurality of types of address remapping processes that are different in hierarchies (sections, sector groups in a section, and sectors in a sector group) of mapping in the mapping information. In addition, a difference in hierarchies of mapping corresponds to a difference in update scale of the mapping information. The update scale of the mapping information is decreased in order of the section→the sector group→each sector in the sector group.

The address remapping unit 132 may solely execute only the second group update process in the sector group update process, and may solely update the in-group management information in the mapping information of the access target physical sector.

In the present embodiment, both the section update process and the sector group update process (the first group update process and the second group update process) are stochastically executed for each access (write access and readout access) to the nonvolatile memory 20.

In the controller 10 according to the present embodiment, it is sufficient if of the address remapping probabilities, a second address remapping probability that is a probability that the second group update process is executed is 0.025% for each write access and 0.01% for each readout access. In contrast to this, it is sufficient if of the address remapping probabilities, a first address remapping probability that is a probability that the section update process is executed is a probability of one eighth of the second address remapping probability for each access (write access and readout access). Specifically, it is sufficient if the first address remapping probability is 0.003125% for each write access and 0.00125% for each readout access.

Thus, the value of the address remapping probability that the address remapping unit 132 performs the address remapping process may differ depending on whether access performed by the access control unit 110 is write access or readout access.

The data inversion unit 134 performs a data inversion process that inverts data (write data) to be written to the memory cell MC to average the number of setting process cycles and the number of resetting process cycles for the respective memory cells MC in the nonvolatile memory 20. Specifically, as the data inversion process, the data inversion unit 134 inverts bits in the write data to be written to the memory cells MC belonging to a write access target physical sector. In the present embodiment, the data inversion unit 134 performs the data inversion process with a predetermined inversion execution probability for each write access by the access control unit 110. The predetermined inversion execution probability is one example of a second probability. That is, the data inversion process in the present embodiment is stochastically executed for each access (write access in this example) to the nonvolatile memory 20.

In the controller 10 according to the present embodiment, the inversion execution probability may be within a range of 40% to 60% both inclusive, and more preferably 50%.

In addition, the data inversion unit 134 adds, to the write data, data inversion information that indicates whether or not the data inversion process has been performed at the time of write access. Specifically, the data inversion unit 134 generates an inversion flag (IV) of 1 bit that indicates whether or not the data inversion process has been executed. For example, the IV=“0” indicates that the data inversion process has not been executed and the write data is not inverted. In addition, the IV=“1” indicates that the data inversion process has been executed and the write data is inverted. The IV is added to the write data, and stored in the nonvolatile memory 20, which makes it possible to decode the sector data into a state before inversion at the time of readout. It is sufficient if the IV is generated on the basis of a process result of the data inversion process, that is, presence or absence of execution of data inversion. The IV may be added to the write data by, for example, the data inversion unit 134, or may be added to the write data by the access control unit 110 or the controller 10 on the basis of the result of the data inversion process (e.g., absence of execution of data inversion=“0” and presence of execution of data inversion=“1”).

The refresh unit 136 performs a refresh process that temporarily changes all memory cells MC in the LRS among access target memory cells in the nonvolatile memory 20 to the HRS to prevent successive readout in the LRS. This refresh process is one example of a resistance state changing process. Specifically, the refresh unit 136 in the present embodiment performs a process of refreshing the memory cells MC corresponding to the access target physical sector with a predetermined refresh execution probability for each access (write access and readout access) to the nonvolatile memory 20 by the controller 10. The predetermined refresh execution probability is one example of a third probability. That is, the refresh process in the present embodiment is stochastically executed for each access (write access in this example) to the nonvolatile memory 20. The refresh process in the present embodiment is a process of changing the variable resistor element VR in the LRS (the low resistance state) among the variable resistor elements VR of the memory cells MC corresponding to the access target physical sector to the HRS (the high resistance state).

It is sufficient if the refresh execution probability is, for example, 0.25% in the controller 10 according to the present technology in consideration of characteristics of the nonvolatile memory 20 in the semiconductor storage device 1 according to the present embodiment, that is, the reference number of successive readout cycles being about 10000 cycles.

The random number generator 138 executes a random number generation process that generates a random number within a predetermined numerical range. The random number generated by the random number generator 138 is used for determination of presence or absence of execution of the wear-leveling process (the address remapping process, the data inversion process, and the refresh process) in respective processors (the address remapping unit 132, the data inversion unit 134, and the refresh unit 136) of the wear-leveling processor 130.

The ECC processor 120 detects an error (a code error) that has occurred in data by parity check, and performs a process for correcting the error. In this example, the ECC processor 120 performs an ECC encoding/decoding process on the sector data at the time of access to a physical sector including a plurality of banks B. The ECC processor 120 includes, for example, an ECC encoder 122 and an ECC decoder 124. The ECC processor 120 typically handles a random error and errors caused by a stuck failure and an RD failure in a small number of bits.

The ECC encoder 122 generates a parity bit upon writing data to the physical sector, and adds the parity bit to the data. For example, upon reception of the write data including the real data and the metadata from the unillustrated host, the controller 10 generates the LA/IV on the basis of the data. In response to this, the ECC encoder 122 generates the parity using the real data, the metadata, and the LA/IV as a payload on the basis of BCH codes. The controller 10 may correct, for example, errors up to a total of 30 bits per 313 bytes by this parity. In this example, the errors during writing are corrected, for example, up to 12 bits per 313 bytes; therefore, the random error may be corrected up to 18 bits.

The ECC decoder 124 performs error check on the basis of an attached parity upon reading data from a sector and corrects a detected error to recover the data. In this example, an error during readout may be corrected, for example, up to 18 bits per 313 bytes.

The nonvolatile memory 20 according to the present technology includes a plurality of memory packages including the group of the tiles T as an access control unit of the microcontroller 70, as described above. The nonvolatile memory 20 stores, for example, user data 220 and various types of management data. Examples of the various types of management data include the address translation table 210 that is backed up, and spare data 240. The various types of management data are described later.

The address translation table 210 is a table that stores mapping information for translating a logical address indicated by an access command received from the unillustrated host into a physical sector address on the nonvolatile memory 20. The address translation table 210 is an address translation table for backup, and is expanded on the work memory 30 during the operation of the semiconductor storage device 1 and is held as the working address translation table 310. It is to be noted that for downsizing of the address translation table 210, an address unit used in the address translation table 210 may be larger than a sector size (320 bytes in this example) suitable for an ECC process. In this example, with the address unit of the address translation table 210 being 8 kilobytes as a section unit, one address in the address translation table 210 may include 32 sets of real data (256 bytes for each), a parity, and a patch.

The address translation table 210 and the working address translation table 310 are synchronized during the operation of the semiconductor storage device 1 under control by the controller 10. This makes it possible for the controller 10 to refer information equivalent to the mapping information stored in the address translation table 210 at high speed by referring to the working address translation table 310. Furthermore, synchronization between the address translation table 210 and the working address translation table 310 makes it possible for the semiconductor storage device 1 to recover the mapping information in the address translation table 310 even at the time of sudden power shutdown, which makes it possible to improve operation reliability.

A plurality of pieces of mapping information (see FIG. 7) including an index and an entry are held in the address translation table 210 for backup. The address translation table 210 uses physical section addresses in the mapping information as indexes (indexes) and holds, as entries associated with the indexes, logical section addresses mapped to (corresponding to) the physical section addresses and the sector management information. That is, the address translation table 210 is an inverted index table using the physical section addresses as indexes with respect to an address translation table in a format in which physical addresses are obtained by using logical addresses as indexes. In the address translation table 210, for example, at the time of referring to an entry, a position where the entry is stored is specified by an index (a physical section address) without search in the table and the position where the entry is stored is directly accessed, which makes it possible to efficiently obtain the entry (the logical section address and the sector management information).

The spare data 240 is data used for replacing, in accordance with the number of hard failures that occur in a sector, the entire sector. More specifically, for example, in a case where the number of bits of errors occur exceeding a predetermined number of bits (e.g., 56 bits) of errors correctable by an ECP engine (not illustrated), which corrects an error in a defective cell in a sector, data that is supposed to be stored in the sector is recorded as spare data.

The work memory 30 in this example temporarily holds the entirety or a part of management data stored in the nonvolatile memory 20, as described above. The work memory 30 is provided for an increase in speed of the semiconductor storage device 1 and wearout prevention. The work memory 30 may be configured to include at least the working address translation table 310.

The working address translation table 310 is a substantial copy of the address translation table 210 for backup held by the nonvolatile memory 20. The “substantial copy” used herein is data that is semantically the same as contents of original data irrespective of a data format. For example, in a case where the working address translation table 310 is data recovered from the address translation table 210 that is data in a compressed format or a redundant format, it can be said that the working address translation table 310 is a substantial copy. The address translation table 210 read out from the nonvolatile memory 20 is held as the working address translation table 310 on the work memory 30 by activation of the semiconductor storage device 1 under control by the access control unit 110. In the present embodiment, reference to the mapping information is generally performed on the working address translation table 310 on the work memory 30. The address translation table 210 for backup is updated only in a case where the working address translation table 310 is updated.

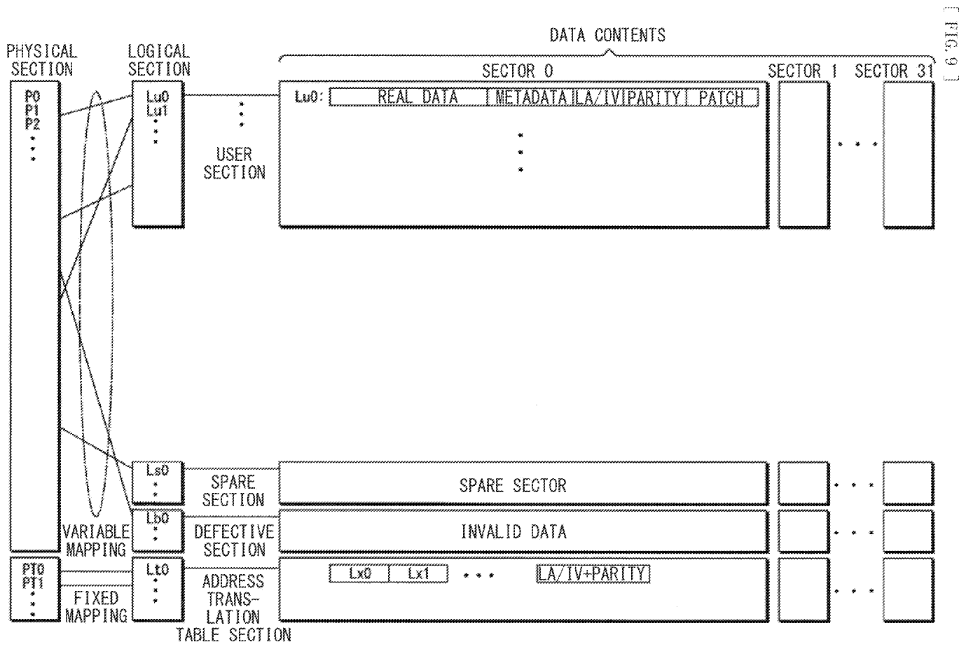

FIG. 9 is a diagram for describing information space of a nonvolatile memory according to the embodiment of the present technology. As illustrated in the diagram, a physical section of the nonvolatile memory 20 is mapped to a logical section through the address translation table 210, and the logical section is associated with data contents.

As illustrated in the diagram, the data contents are stored as sector data in any of a plurality of sectors (32 sectors in this example). A user section is stored in association with user data (real data and metadata) in the data contents. A spare section is stored in association with a spare sector to be used as a replacement. A defective section is stored in association with data indicated by a physical address where a hard failure (a hard error) has occurred. A address translation table section is stored in association with the address translation table 210. It is to be noted that mapping between the address translation table section and the physical section is fixed. That is, the physical section is separated into a normal physical section that is able to be optionally mapped to a normal logical section (a user section, a spare section, and a failure section) by the address translation table 210 and a mapping-fixed physical section for storage that stores the address translation table itself and of which mapping to the address translation table section is fixed.

Fixing mapping between the address translation table section and the physical section makes it possible for the controller 10 to read out the address translation table 210 for backup from the physical section without referring to the address translation table at the time of activation of the semiconductor storage device 1 and expand the working address translation table 310 on the work memory 30. The address translation table section mapped to a mapping-fixed physical section is not mapped to a logical address usable in the unillustrated host, and is therefore not able to be referred to from side of the host. Accordingly, even if mapping between the address translation table section and the physical section is fixed, no influence by malicious access from the host, or the like is received.

It is to be noted that in the present embodiment, the size of the section (the physical section and the logical section) is 8 kilobytes; however, the present technology is not limited thereto. The size of the section may be changed appropriately in accordance with specifications of the semiconductor storage device 1 and a cost ratio between the nonvolatile memory 20 and the work memory 30. For example, the data amount of the working address translation table 310 is decreased with an increase in the size of the section, which makes it possible to expand the work memory 30 having a small capacity. In contrast, the data mount to be accessed is decreased at the time of one mapping update in the address remapping process, which makes it possible to suppress a decrease in performance with execution of the address remapping process. Furthermore, in a case where the size of the section is small, it is possible to decrease the unit of the spare section, thereby improving a relief rate at the time of a write failure, for example.

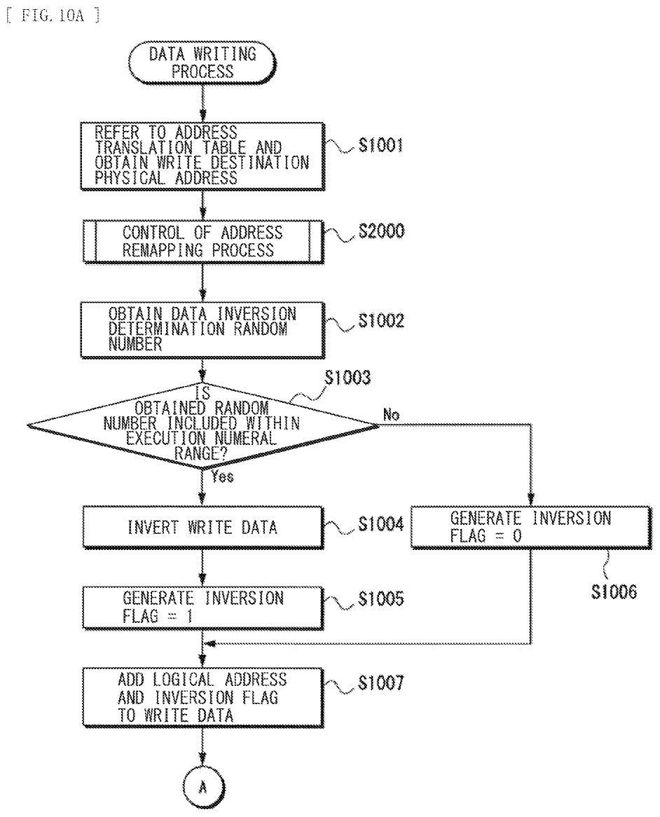

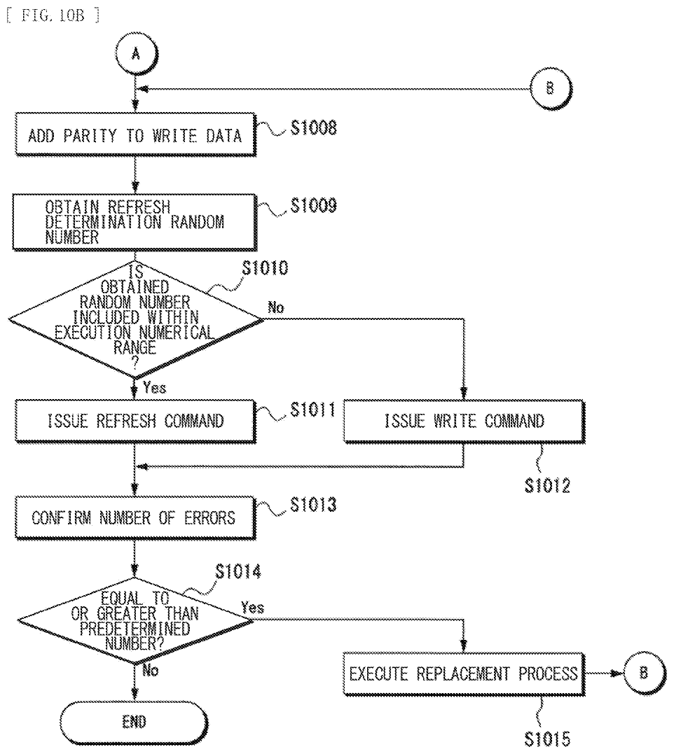

FIG. 10A and FIG. 10B are flowcharts for describing an example of a data writing process in the semiconductor storage device 1 according to the embodiment of the present technology.

The writing process includes the wear-leveling process (the address remapping process, the data inversion process, and the refresh process) as described below.

The writing process is executed, for example, in a case where the controller 10 receives a normal write access command from the unillustrated host. That is, as illustrated in FIG. 10A, upon reception of the write command by the controller 10, the access control unit 110 obtains a physical sector address of a write destination physical sector by the address translation process. Specifically, the access control unit 110 refers to the working address translation table 310 on the work memory 30, and translates an access destination logical section address (herein, a write destination logical section address) to obtain a write destination physical sector address (S1001).

The access control unit 110 outputs, for example, the access destination logical section address and the write destination physical sector address to the wear-leveling processor 130. The address remapping unit 132 included in the wear-leveling processor 130 performs control of the address remapping process on the basis of such output (S2000). Control of the address remapping process involved by the data writing process is described later. After the address remapping unit 132 performs control of the address remapping process, the address remapping unit 132 outputs a process result to the wear-leveling processor 130. Examples of the process result of the address remapping process include flag information that indicates presence or absence of execution of the address remapping process.

The data inversion unit 134 included in the wear-leveling processor 130 starts control of the data inversion process on the basis of output of the result of the address remapping process. Specifically, the data inversion unit 134 obtains a data inversion determination random number for determining presence or absence of execution of the data inversion process from the random number generator 138 (S1002). In a case where a data inversion random number is obtained, the data inversion unit 134 determines whether or not the obtained random number is included within an execution numeral range (S1003). Here, the execution numeral range is a numeral range including a number of numerical values corresponding to an inversion execution probability (e.g., 50%) in the same numerical range as a numerical range (0 to n) of data inversion random numbers that are generatable by the random number generator 138. In a case where the data inversion unit 134 determines that the obtained data inversion determination random number is included within the execution numerical range (Yes in S1003), the data inversion unit 134 performs the data inversion process on the write data (S1004). Thus, the data inversion process is stochastically executed on the basis of, for example, an inversion execution probability of 50% for each write access.

Specifically, the data inversion unit 134 performs a process of inverting a bit value (“1”→“0”, “0”→“1”) in the write data as the data inversion process on the write data. At the time of data inversion, the write data is data including real data of 256 bytes and metadata of 8 bytes received from the host together with the write access command. In the present embodiment, the data inversion unit 134 inverts all bit values in the write data in the data inversion process.

It is to be noted that the data inversion unit 134 may be configured to invert some of bits in the write data in the data inversion process. In this case, which bit is to be inverted may be randomly determined on the basis of, for example, the random number generated by the random number generator 138.

In a case where the data inversion process is performed, the data inversion unit 134 executes the data inversion process to generate the inversion flag IV (e.g., “1”) that indicates that the write data is inverted (S1005). In contrast, in a case where the data inversion unit 134 determines that the obtained data inversion determination random number is not included within the execution numerical range (No in S1003), the data inversion unit 134 generates the inversion flag IV (e.g., “0”) that indicates that the data inversion process has not been executed and the write data is not inverted (S1006). The generated inversion flag IV is outputted to the access control unit 110 through the wear-leveling processor 130.

As described above, the data inversion unit 134 stochastically executes control of the data inversion process (S1002 to S1006), and even in a case where an access pattern for the write data is biased, write wearout and readout wearout are handled by reducing a probability of changing each memory cell MC to the LRS while reducing the number of rewrite cycles in the memory cells MC.

In a case where the inversion flag IV is outputted, the access control unit 110 adds the inversion flag IV together with a logical sector address LA of 31 bits to the write data (S1007). Thus, another data (LA+IV) of 4 bytes (32 bits) is added to the write data.

The logical sector address added to the write data is used for detection and correction of a malfunction (e.g., garbled data) of data in a communication path in the semiconductor storage device 1 or on the work memory 40. For example, the access control unit 110 determines whether or not the logical sector address added to data in the access target physical sector and the logical sector address obtained from the working address translation table 310 on the basis of the received logical address match each other at the time of access to the physical sector. Here, in a case where the two logical sector addresses do not match each other, the access control unit 110 determines that the data in the communication path in the semiconductor storage device 1 or on the work memory 30 has a malfunction (e.g., garbled data), and is able to correct the malfunction of the data.

Next, the access control unit 110 outputs the write data to the ECC encoder 122, and adds a parity to the write data (S1008 in FIG. 10B). The ECC encoder 122 generates the parity using the real data, the metadata, and the LA/IV as a payload for the outputted write data on the basis of BCH codes. In a case where the parity is added to the write data, the access control unit 110 outputs the write data to the wear-leveling processor 130. The refresh unit 136 of the wear-leveling processor 130 starts control of the refresh process on the basis of this.

Specifically, the refresh unit 136 obtains, from the random number generator 138, a refresh determination random number for determining presence or absence of execution of the refresh process (S1009). In a case where the refresh determination random number is obtained, the refresh unit 136 determines whether or not the obtained random number is included within an execution numerical range (S1010). Here, the execution numerical range is a numerical range including a number of numerical values corresponding to a refresh execution probability (e.g., 0.25%) in the same numerical range as the numerical range (0 to n) of data inversion random numbers that are generatable by the random number 138. In a case where the refresh unit 136 determines that the obtained refresh determination random number is included within the execution numerical range (Yes in S1010), the refresh unit 136 issues a refresh command to the nonvolatile memory 20 (S1011). Thus, the refresh process is stochastically executed on the basis of, for example, a refresh execution probability of 0.25% for each write access in which the write data is to be written to the memory cells MC belonging the access target physical sector. In a case where the refresh process is executed, the refresh unit 136 outputs a process result (e.g., “1”) that indicates that the refresh process has been performed, to the access control unit 110 through the wear-leveling processor 130.

In the present embodiment, the refresh command is a command for writing data after temporarily changing the memory cells MC in the LRS to the HRS. The refresh unit 136 issues the write data to the nonvolatile memory 20 with issuing of the refresh command. Thus, the write data is written to the nonvolatile memory 20 concurrently with the refresh process. The write data has, for example, 320 bytes. Specifically, the write data is divided into ten pages of 32 bytes, and is written to a plurality of memory cells MC belonging the access target physical sector.

In contrast, in a case where the refresh unit 136 determines that the obtained refresh determination random number is not included within the execution numerical range (No in S1010), the refresh unit 136 outputs a process result (e.g., “0”) that indicates that the refresh process has not been performed, to the access control unit 110 through the wear-leveling processor 130. The access control unit 110 issues a write command together with the write data to the nonvolatile memory 20 on the basis of the process result (S1012). Thus, the write data is written to a plurality of memory cells MC belonging to the access target physical sector by the write command.

In the present embodiment, the refresh command is desired to be mounted on the controller 10 as a command specific to the refresh process. Specifically, the refresh command may be a command different from a write command that is to be issued by the access control unit 110 at the time of write access in which data is written to the memory cells MC corresponding to the access target physical sector, and a readout command that is to be issued by the access control unit 110 at the time of readout access in which data is read out from the memory cells MC corresponding to the access target physical sector. This makes it possible for the controller 10 to achieve an increase in speed of the refresh process. It is to be noted that the present technology is not limited thereto, and the refresh process may be implemented, for example, by issuing a data loading command in combination with a normal readout command or write command. Here, the data loading command is a command for writing predetermined data (all bits of “0” or all bits of “1”) to the memory cells without inputting data from the controller 10.

As described above, the refresh unit 136 stochastically executes control of the refresh process (S1009 to S1011), and reduces a probability that the number of successive readout cycles in each memory cell MC reaches the reference number of successive readout cycles to handle write failures due to successive readout.

Next, in a case where the data is written to the nonvolatile memory 20, the access control unit 110 performs confirmation of the number of errors (S1013). After issuing the refresh command or the write command, the access control unit 110 issues a mode register readout command after a lapse of predetermined time, and confirms the number of bits where writing fails (the number of errors) in the write data. That is, the number of the memory cells MC where a write failure has occurred in the physical sector by execution of the write command or the refresh command immediately before the mode register readout command is obtained by the mode register readout command.

Next, the access control unit 110 determines whether or not the confirmed number of errors is equal to or greater than a predetermined number (e.g., a number of 13 bits) (S1014). In a case where the number of errors is equal to or less than a number of 12 bits (No in S1014), after error correction in which the errors are corrected by the ECC process, the access control unit 110 ends the write process. In contrast, in a case where the access control unit 110 determines that the number of errors is equal to or greater than the predetermined number (Yes in S1014), the access control unit 110 executes a replacement process (S1015). In the replacement process, the access control unit 110 allocates a write destination of the write data to a physical sector address that indicates a spare sector stored in the spare data 240. The access control unit 110 executes processes after addition of the parity to the write data (S1008) again.

As described above, the access control unit 110 of the controller 10 executes the wear-leveling process on a certain physical sector, and thereafter executes the data writing process.

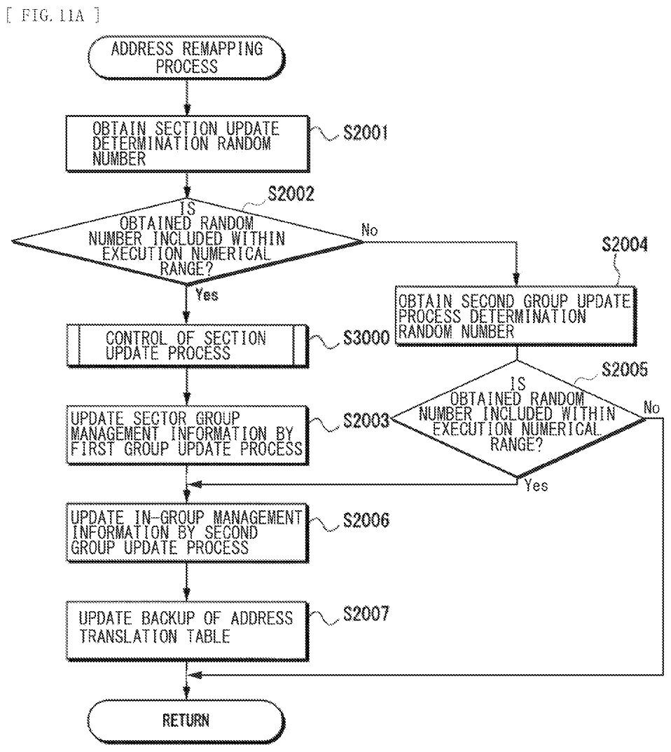

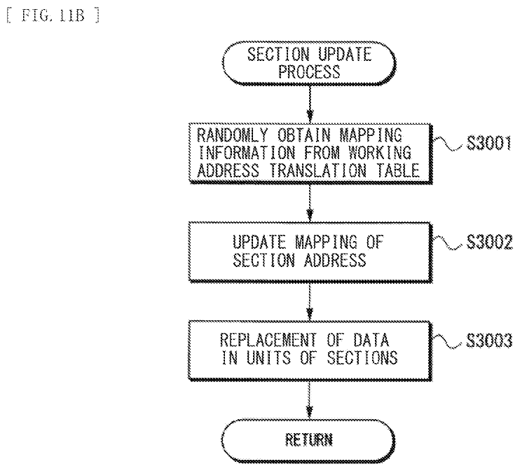

FIG. 11A is a flowchart for describing an example of the address remapping process in the semiconductor storage device 1 according to the present embodiment. In addition, FIG. 11B is a flowchart for describing an example of a section update process of the address remapping process in the semiconductor storage device 1 according to the present embodiment. Here, description is given of control of the address remapping process (S2000) during the data writing process described above with reference to FIGS. 11A and 11B.

In a case where the access control unit 110 outputs the access destination logical section address and the write destination physical sector address to the wear-leveling processor 130 (S1001 in FIG. 10A), the address remapping unit 132 obtains a section update determination random number for determining presence or absence of execution of the section update process on the basis of such output (S2001). In a case where the section update determination random number is obtained, the address remapping unit 132 determines whether or not the obtained random number is included within an execution numerical range (S2002). Here, the execution numerical range is a numerical range including a number of numerical values corresponding to a first address remapping probability (e.g., 0.003125%) at the time of write access in the same numerical range as a numerical range (0 to n) of section update determination random numbers that are generatable by the random number 138. In a case where the address remapping unit 132 determines that the obtained section update determination random number is included within the execution numerical range (Yes in S2002), the address remapping unit 132 performs the section update process (S3000). Thus, control of the section update process is stochastically executed on the basis of, for example, the first address remapping probability of 0.003125% for each write access.

Thus, the address remapping unit 132 determines whether or not to perform the address remapping process (the section update process in this example) for each access (each write access in this example) on the basis of the random number generated by the random number generator 138.

Here, description is given of the section update process with reference to FIG. 11B. The address remapping unit 132 first randomly obtains one piece of mapping information from the working address translation table 310 in the section update process (S3001). It is sufficient if the mapping information obtained here is not mapping information corresponding to the access target physical sector of the access control unit 110. Here, the address remapping unit 132 may determine one piece of mapping information as an obtainment target on the basis of, for example, a random number generated by the random number generator 138. For example, the address remapping unit 132 may obtain a random number within a numerical range corresponding to a logical section address in the working address translation table 310 from the random number generator 138, and may obtain mapping information associated with the logical section address indicated by the value of the obtained random number.

Next, the address remapping unit 132 updates the working address translation table 310 to update mapping of the section address (S3002). Specifically, the address remapping unit 132 maps the physical section address (e.g., “PS001”) mapped to the access destination logical section address (e.g., “LS001”) to a physical section address (e.g., “PS002”) in the one piece of mapping information randomly obtained. Furthermore, the address remapping unit 132 maps the physical section address (“PS001”) mapped to the access destination logical section address (LS001) to a logical section address (e.g., “LS002”) in the one piece of mapping information randomly obtained. Thus, one physical section address (PS001) corresponding to one logical section address (LS001) that specifies the access target physical sector is replaced with another physical section address (PS002) that is randomly selected and different from the one physical section address.

The address remapping unit 132 updates mapping of the section address, and performs replacement of data in units of sections (S3003), and returns to control of the address remapping update process. Specifically, the address remapping unit 132 replaces data of the physical sector in the physical section indicated by the physical section address (“PS001”) before update mapped to the access destination logical section address (“LS001”) with data of the physical sector in the physical section indicated by a newly mapped physical section address (“PS002”) after the update. Thus, date stored in the physical sector specified by another physical section address (PS002) randomly selected is replaced with data stored in the physical sector specified by the physical section address (“PS001”) before the update.

Returning to FIG. 11A, in a case where the address remapping unit 132 executes the section update process, the address remapping unit 132 executes the first group update process described above to update the sector group management information in the mapping information of the working address translation table 310 (S2003). Specifically, the address remapping unit 132 updates the sector group management information corresponding to the access destination logical section address (“LS001”). The address remapping unit 132 randomly determines an update value of the sector group management information in the first group update process. During the first group update process, the address remapping unit 132 may obtain a random number within the first numerical range described above and may set the obtained random number as the update value of the sector group management information. After the address remapping unit 132 executes the first group update process, the address remapping unit 132 executes the second group update process described above to update the in-group management information in the mapping information of the working address translation table 310 (S2006).

In contrast, in a case where the address remapping unit 132 determines that the obtained section update determination random number is not included within the execution numerical range (No in S2002), the address remapping unit 132 obtains a second group update process determination random number for determining presence or absence of execution of the second group update process (S2004). In a case where the second group update process determination random number is obtained, the address remapping unit 132 determines whether or not the obtained random number is included within an execution numerical range (S2005). Here, the execution numerical range is a numerical range including a number of numerical values corresponding to a second address remapping probability (e.g., 0.025%) during write access in the same numerical range as a numerical range (0 to n) of second group update process determination random numbers that are generatable by the random number 138. In a case where the address remapping unit 132 determines that the obtained second group update process determination random number is included within the execution numerical range (Yes in S2005), the address remapping unit 132 executes the second group update process described above to update the in-group management information in the mapping information of the working address translation table 310 (S2006).

The update value of the in-group management information in the second group update process is randomly determined. For example, during the second group update process, the address remapping unit 132 may obtain a random number within the second numerical range described above from the random number generator 138 and may set the obtained random number as the update value of the in-group management information.

In a case where the address remapping unit 132 updates the in-group management information, the address remapping unit 132 updates the address translation table 210 for backup on the nonvolatile memory 20 and synchronizes the address translation table 210 for backup with the working address translation table 310 (S2007). In this example, after the address remapping unit 132 updates the address translation table 210, the address remapping unit 132 returns to S1002 (see FIG. 10A) of the data writing process.

The number of cycles of reference to the address translation table 210 for backup that is an inverted index table is leveled in association with leveling of the access target physical sectors by the address remapping process. Accordingly, as illustrated in FIG. 9, it is possible to level wearout of the memory cells MC that store data of the address translation table 210 in spite of storing in a region where mapping is fixed.

As described above, the address remapping unit 132 updates the address translation table 210 to execute the address remapping process for handling write wearout of the memory cells MC due to concentration of access to a specific sector in units of sections, units of sector groups, or units of logical sectors in the sector group.

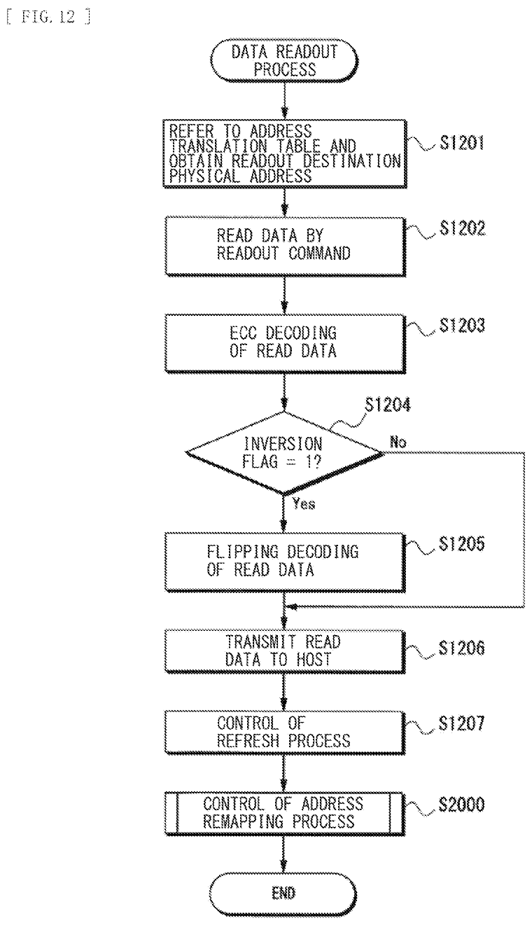

FIG. 12 is a flowchart for describing an example of a data readout process in the semiconductor storage device 1 according to the embodiment of the present technology. The readout process includes the wear-leveling process as described below. The readout process is executed, for example, in a case where the controller 10 receives a normal readout access command from the unillustrated host.

That is, as illustrated in the diagram, upon reception of the readout command by the controller 10, the access control unit 110 obtains the physical sector address of a readout destination physical sector by the address translation process. Specifically, the access control unit 110 refers to the working address translation table 310 on the work memory 30, and translates an access destination logical section address (here, a readout destination logical section address) to obtain a readout destination physical sector address (S1201).

Next, the access control unit 110 performs readout of data from the readout destination physical sector address based on the readout command (S1202). In a case where data is read out from the readout destination physical sector of the nonvolatile memory by the readout command issued by the access control unit 110, in response to this, the access control unit 110 outputs the read data to the ECC decoder 124 of the ECC processor 120 to perform ECC decoding (S1203). The ECC decoder 124 performs an ECC decoding process on the basis of an parity added to the read data. For example, the ECC decoder 124 performs error check on the basis of the parity added to the read data and corrects a detected error to recover the data. In a case where the ECC decoding is performed, the access control unit 110 confirms an inversion flag (IV) added to the read data. In a case where the access control unit 110 determines that the inversion flag (IV) is “1” (Yes in S1204), the access control unit 110 determines that the read data is inverted during writing, and performs a flipping decoding process on the read data (S1205). Specifically, the access control unit 110 inverts all bits of real data and metadata in the read data. In contrast, in a case where the access control unit 110 determines that the inversion flag (IV) is “0” (No in S1204), the access control unit 110 determines that the read data is not inverted during writing, and skips the flipping decoding process.

Next, the access control unit 110 transmits the read data to the host (S1206). After the access control unit 110 transmits the read data to the host, the access control unit 110 outputs a transmission result to the wear-leveling processor 130. The refresh unit 136 in the wear-leveling processor 130 performs control of the refresh process on the basis of this (S1207). Here, contents of the control of the refresh process are similar to those during the write process (S1009 to S1011 in FIG. 10B). It is to be noted that in the refresh process during the data readout process, in a case where the refresh unit 136 determines that the obtained refresh determination random number is not included within the execution numerical range (No in S1010), the refresh unit 136 ends the control of the refresh process. In addition, in the refresh process during the data readout process, the refresh unit 136 issues the read data having been subjected to the ECC decoding process, together with the refresh command to the nonvolatile memory 20. Thus, the read data having been subjected to the ECC decoding process is written back to the readout destination physical sector address. In addition, in a case where the refresh unit 136 does not issue the refresh command during the data readout process, the refresh unit 136 may issue the read data having been subjected to the ECC decoding process, together with the write command to the nonvolatile memory 20.

Next, the address remapping unit 132 in the wear-leveling processor 130 performs control of the address remapping process (S2000). Here, contents of the control of the address remapping process during the data readout process are similar to those during the data writing process (see FIG. 11A). Note that in the address remapping process in the data readout process, the first address remapping probability related to execution of the section update process is 0.00125%. In addition, in the address remapping process in the readout process, the second address remapping probability related to execution of the second group update process is 0.01%. In a case where the address remapping process in the address remapping unit 132 ends, the access control unit 110 ends the data readout process.

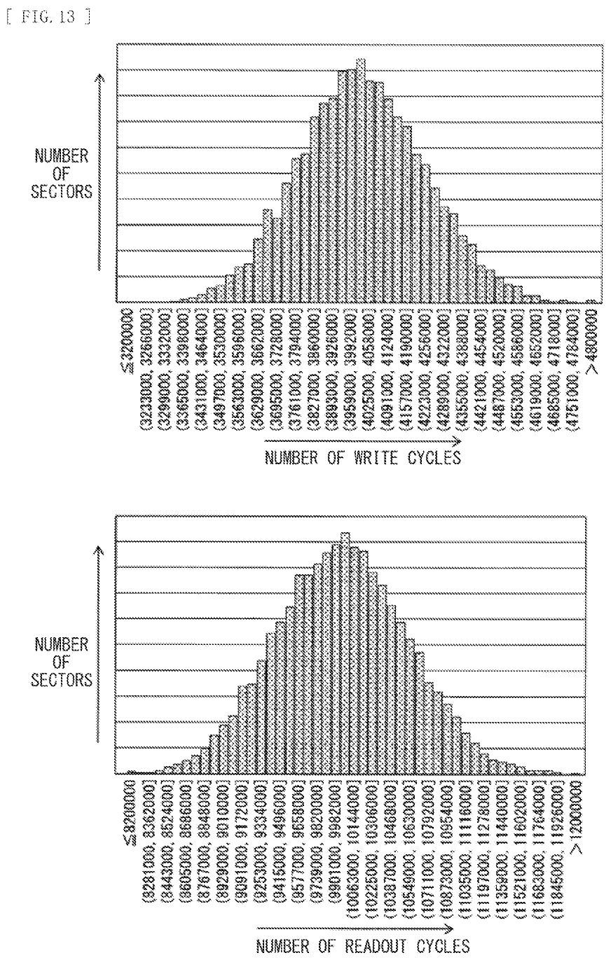

The following description is given of an effect of the wear-leveling process to be executed by the controller 10 according to the present embodiment with a simulation result. FIG. 13 is a histogram that indicates a simulation result of the address remapping process according to the present embodiment. In this example, the section update process and the sector group update process in the address remapping process were implemented by software, and an effect of leveling access to the memory cells MC was simulated. In this simulation, a Monte Carlo method was used. In this simulation, it was assumed that the structure of a nonvolatile memory included 16384 sectors=512 sections×32 sectors. In addition, in software implementation of this simulation, the section update process was executed in accordance with the first address remapping probability (0.003125% for each write access and 0.00125% for each readout access) described above by generating a pseudo random number. During the section update process, the sector group update process (the first group update process and the second group update process) was also executed. Furthermore, in the software implementation of this simulation, the second group update process of the sector group update process was executed in accordance with the second address remapping probability (0.025% for each write access and 0.01% for each readout access) by generating a pseudo random number.

First, as a simulation of the address remapping process, the write access was intensively performed on a specific logical sector to calculate the number of write (setting or resetting) cycles of data to each physical sector. Specifically, 16384×4.0e6 cycles (an average value of the lifetime number of write cycles for each physical sector in the present embodiment) of write access were concentrated on a logical sector address that indicated the specific logical sector to calculate the number of write cycles of data to each physical sector. An upper stage in FIG. 13 is a histogram that illustrates a distribution of the number of sectors (physical sectors in this example) with respect to the number of write cycles calculated in this simulation. It is to be noted that the average value of the lifetime number of write cycles was determined as a lifetime write capacity (2 exabytes) expected in the nonvolatile memory 20/the capacity (512 gigabytes) of the nonvolatile memory 20.

Furthermore, as the simulation of the address remapping process, readout access to a specific logical sector was intensively performed to calculate the number of readout cycles of data from each physical sector. Specifically, 16384×1.0e7 cycles (an average value of the lifetime number of readout cycles from each physical sector in the present embodiment) of readout access were concentrated on a logical sector address that indicated the specific logical sector to calculate the number of readout cycles of data from each physical sector. A lower stage in FIG. 13 is a histogram that illustrates a distribution of the number of sectors (physical sectors in this example) with respect to the number of readout cycles calculated in this simulation. It is to be noted that the average value of the lifetime number of readout cycles was determined as a lifetime readout capacity (5 exabytes) expected in the nonvolatile memory 20/the capacity (512 gigabytes) of the nonvolatile memory 20.

As a result of the simulation described above, as illustrated in the upper stage in FIG. 13, it was confirmed that even in a case where write access extremely biased toward the logical sector address that indicated the specific logical sector was performed, it was possible to average the number of write cycles by the address remapping process to be equal to or less than an assumed average value of the lifetime number of write cycles for 99.9% of the physical sectors on the nonvolatile memory (4.0e6)+20%=4.8e6 write cycles.

In addition, as a result of the simulation described above, as illustrated in the lower stage in FIG. 13, it was confirmed that even in a case where readout access extremely biased toward the logical sector address that indicated the specific logical sector was performed, it was possible to average the number of readout cycles by the address remapping process to be equal to or less than an assumed average value of the lifetime number of readout cycles for 99.9% of the physical sectors on the nonvolatile memory (1.0e7)+20%=1.2e7 readout cycles.

Thus, as the wear-leveling process, the controller 10 according to the present technology executes the section update process of the address remapping process, for example, with a probability of 0.003125% for each write access and a probability of 0.00125 for each readout access together with the sector group update process, and executes the second group update process of the address remapping process, for example, with a probability of 0.025% for each write access and a probability of 0.01% for each readout access, which makes it possible to average the number of write cycles and the number of readout cycles for the memory cells MC belonging to each physical sector.

In addition, the controller 10 according to the present technology stochastically performs the data inversion process as the wear-leveling process. For example, a probability that the bit value changes for each writing can be regarded as 50% by inverting data with a probability of 50% at the time of write access. Accordingly, the controller 10 is able to average the number of rewrite cycles for the memory cells MC even in a biased data pattern (e.g., all bits of “0” or all bits of “1”) to level the write wearout. In addition, performing data inversion with a probability of 50% at the time of write access and executing the section update process and the sector group update process with a predetermined probability (e.g., 0.00125%) for each read access makes it possible to set the lifetime number of LRS readout cycles for each memory cell MC, that is, the number of times that each memory cell MC is in the LRS out of the lifetime number of readout cycles to about 50%. This also applies to a biased data pattern.

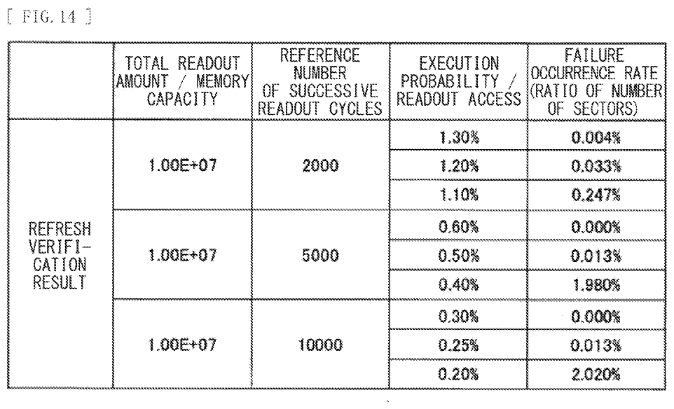

In addition, FIG. 14 is a diagram illustrating a verification result of the refresh process according to the present embodiment. In the nonvolatile memory 20 according to the present embodiment, for example, in a case where the reference number of successive readout cycles was 10000 cycles, the refresh process was verified with a refresh execution probability for each readout access (referred to as “execution probability/readout access” in FIG. 14) being 0.30%, 0.25%, and 0.20%. As illustrated in FIG. 14, with the refresh execution probability of 0.30%, the occurrence rate of write failures due to successive readout was less than 0.001% (referred to as “0.000%” in FIG. 14), with the refresh execution probability of 0.25%, the occurrence rate of write failures due to successive readout was 0.013%, and with the refresh execution probability of 0.20%, the occurrence rate of write failures due to successive readout was 2.020%. It is to be noted that in FIG. 14, the occurrence rate of write failures due to successive readout is referred to as a “failure occurrence rate”. In addition, the “failure occurrence rate” was determined as a ratio of the number of sectors (a ratio of the number of physical sectors in which a write failure has occurred due to successive readout in the total number of physical sectors).

In this example, in a case where the refresh execution probability is 0.30%, while the occurrence rate of write failures due to successive readout is significantly decreased to less than 0.001%, an influence on operation performance of the semiconductor storage device 1 (e.g., a decrease in operation performance) is large. In addition, in a case where the refresh execution probability is 0.20%, the occurrence rate of write failures due to successive readout is equal to or greater than 2% as described above, and reduction in write failures is not sufficient. In contrast, in a case where the refresh execution probability is 0.25%, it is possible to suppress the occurrence rate of write failures due to successive readout to about 0.01% as described above; therefore, it is possible to provide compensation (relief) for write failures by a small number of spare addresses in the spare section, and the influence on the operation performance of the semiconductor storage device 1 is extremely small. Accordingly, in a case where the reference number of successive readout cycles is 10000 cycles, an optimum refresh execution probability is 0.25%.

In addition, in the nonvolatile memory 20, for example, in a case where the reference number of successive readout cycles was 5000 cycles, the refresh process was verified with a refresh execution probability for each readout access being 0.60%, 0.50%, and 0.40%. As illustrated in FIG. 14, in this example, with the refresh execution probability of 0.60%, the occurrence rate of write failures due to successive readout was less than 0.001%, with the refresh execution probability of 0.50%, the occurrence rate of write failures due to successive readout was 0.013%, and with the refresh execution probability of 0.40%, the occurrence rate of write failures due to successive readout was 1.980%.

In this example, in a case where the refresh execution probability for each readout access is 0.60%, the occurrence rate of write failures is less than 0.001%, but the influence on operation performance of the semiconductor storage device 1 is increased. In addition, in a case where the refresh execution probability is 0.40%, the occurrence rate of write failures due to successive readout is about 2%; therefore, reduction in write failures is not sufficient. In contrast, in a case where the refresh execution probability is 0.50%, it is possible to suppress the occurrence rate of write failures due to successive readout to about 0.01%, and the influence on the operation performance of the semiconductor storage device 1 is also relatively small; therefore, such a refresh execution probability is suitable.

In addition, in the nonvolatile memory 20, for example, in a case where the reference number of successive readout cycles was 2000 cycles, the refresh process was verified with a refresh execution probability for each readout access being 1.30%, 1.20%, and 1.10%. As illustrated in FIG. 14, with the refresh execution probability of 1.30%, the occurrence rate of write failures due to successive readout was 0.004%, with the refresh execution probability of 1.20%, the occurrence rate of write failures due to successive readout was 0.033%, and with the refresh execution probability of 1.10%, the occurrence rate of write failures due to successive readout was 0.247%.

In this example, in a case where the refresh execution probability for each readout access is 1.30%, the occurrence rate of write failures is decreased to 0.004%, but the influence on the operation performance of the semiconductor storage device 1 is increased. In addition, in a case where the refresh execution probability is 1.10%, the occurrence rate of write failures due to successive readout is equal to or greater than 0.2%; therefore, reduction in write failures is not sufficient. In contrast, in a case where the refresh execution probability is 1.20%, it is possible to suppress the occurrence rate of write failures due to successive readout to about 0.03%, and the influence on the operation performance of the semiconductor storage device 1 is also relatively small; therefore, such a refresh execution probability is suitable.

As described above, according to the present technology, it is possible to provide a controller that makes it possible to reduce write failures by eliminating localization of wearout of cells in a memory in accordance with characteristics of a Xp-ReRAM and maximize a lifetime of the memory, a semiconductor storage device, and a wear-leveling processing method in the device.

The embodiments described above are examples for describing the present technology, and the present technology is not limited only to the embodiments. The present technology can be carried out in various modes without departing from the gist thereof.

For example, in the methods disclosed in the present specification, the steps, the operations, or the functions may be executed in parallel or in different order as long as a contradiction does not arise in the result. The steps, the operations, and the functions have been described as examples, and some of the steps, the operations, and the functions may be omitted or combined into one, or other steps, operations or functions may be added without departing from the gist of the present invention.

In addition, although various embodiments are disclosed in the present specification, a specific feature (technical matter) in one embodiment may be added to another embodiment while appropriately improving the feature, or the feature may be replaced by a specific feature in the other embodiment. Such an embodiment is included in the gist of the present technology.

In addition, the present technology may be configured to include the following technical matters.

(1)

A controller that controls an operation of a semiconductor storage device including a writable nonvolatile memory, the controller including:

an access control unit that controls access to data storage regions based on some of a plurality of memory cells in the nonvolatile memory in accordance with an address translation table holding mapping information that indicates a correspondence between physical addresses specifying the data storage regions and logical addresses; and

a wear-leveling processor that performs a wear-leveling process that levels wearout of the plurality of memory cells that is caused by the access,

the wear-leveling processor performing the wear-leveling process with a predetermined probability at each time of the access.

(2)

The controller according to (1), in which the wear-leveling processor includes a table update unit that performs a table update process with a first probability at each time of the access, the table update process that updates the mapping information in the address translation table.

(3)

The controller according to (2), in which the table update unit replaces one physical address, corresponding to one logical address of the logical addresses, of the physical addresses with another physical address, the one logical address specifying the data storage region as a target of the access, and the other physical address being different from the one physical address and randomly selected.

(4)

The controller according to (3), in which the table update unit replaces data stored in the data storage region specified by the other physical address with data stored in the data storage region specified by the one physical address.

(5)

The controller according to any one of (2) to (4), including a random number generator that generates a random number, in which

the table update unit determines whether or not to perform the table update process on the basis of a random number generated by the random number generator at each time of the access.

(6)

The controller according to any one of (2) to (5), in which

the address translation table holds the mapping information for each storage region that stores a predetermined number of the data storage regions, and

the table update unit performs the table update process for each of the storage regions that store the data storage region as a target of the access.

(7)

The controller according to (6), in which the table update unit performs the table update process for every several data storage regions of the data storage regions in the storage region.

(8)

The controller according to (7), in which the table update unit performs the table update process on each of the several data storage regions of the data storage regions in the storage region.

(9)

The controller according to any one of (2) to (8), in which

the access controlled by the access control unit includes write access and readout access, the write access in which data is written to some memory cells, corresponding to the data storage region, of the memory cells, and the readout access in which data is read out from some memory cells, corresponding to the data storage region, of the memory cells, and

a value of the first probability that the table update unit performs the table update process differs depending on whether the access is the write access or the readout access.

(10)

The controller according to any one of (1) to (9), in which the wear-leveling processor includes a data inversion processor that performs, in a case where the access controlled by the access control unit is write access, a data inversion process that inverts bits in write data to be written to the memory cells with a second probability at each time of the write access, the write access in which data is written to some memory cells, corresponding to the data storage region, of the memory cells.

(11)

The controller according to (10), in which the data inversion processor adds, to the write data, data inversion information that indicates whether or not the data inversion process has been performed at the time of the write access.

(12)

The controller according to any one of (1) to (11), in which

the nonvolatile memory includes a cross-point resistive RAM,

a plurality of the memory cells each includes a variable resistor element that is reversibly changeable between a low resistance state and a high resistance state, and

the wear-leveling processor includes a resistance state changing unit that performs a resistance state changing process with a third probability at each time of the access to the data storage region, the resistance state changing process that changes, to the high resistance state, the variable resistor elements in the low resistance state among the variable resistor elements of some memory cells, corresponding to the data storage region as a target of the access, of the memory cells.

(13)

The controller according to (12), in which

the resistance state changing unit issues a resistance state changing command for executing the resistance state changing process to the nonvolatile memory including the data storage region as the target of the access to execute the resistance state changing process, and

the resistance state changing command is a command different from a write command and a readout command, the write command being issued by the access control unit at a time of write access in which data is written to some memory cells, corresponding to the data storage region as the target of the access, of the memory cells, and the readout command being issued by the access control unit at a time of readout access in which data is read out from some memory cells, corresponding to the data storage region as the target of the access, of the memory cells.

(14)

A semiconductor storage device provided with a nonvolatile memory and a controller, the nonvolatile memory including a plurality of writable nonvolatile memory cells, the controller that controls the nonvolatile memory, the controller including:

an access control unit that controls access to data storage regions based on some of a plurality of memory cells in the nonvolatile memory in accordance with an address translation table holding mapping information that indicates a correspondence between physical addresses specifying the data storage regions and logical addresses; and

a wear-leveling processor that performs a wear-leveling process that levels wearout of the plurality of memory cells that is caused by the access,

the wear-leveling processor performing the wear-leveling process with a predetermined probability at each time of the access.

(15)

The semiconductor storage device according to (14), in which the wear-leveling processor includes a table update unit that performs a table update process with a first probability at each time of the access, the table update process that updates the mapping information in the address translation table.

(16)

The semiconductor storage device according to (14) or (15), in which the wear-leveling processor includes a data inversion processor that performs, in a case where the access controlled by the access control unit is write access, a data inversion process that inverts bits in write data to be written to the memory cells with a second probability at each time of the write access, the write access in which data is written to some memory cells, corresponding to the data storage region, of the memory cells.

(17)

The semiconductor storage device according to any one of (14) to (16), in which

the nonvolatile memory includes a cross-point resistive RAM,

the plurality of memory cells each includes a variable resistor element that is reversibly changeable between a low resistance state and a high resistance state, and

the wear-leveling processor includes a resistance state changing unit that performs a resistance state changing process with a third probability at each time of the access to the data storage region, the resistance state changing process that changes, to the high resistance state, the variable resistor elements in the low resistance state among the variable resistor elements of some memory cells, corresponding to the data storage region as a target of the access, of the memory cells.

(18)

A wear-leveling processing method in which in a semiconductor storage device including a nonvolatile memory that includes a plurality of writable nonvolatile memory cells, wearout of the plurality of memory cells is leveled, the wear-leveling processing method including:

controlling access to data storage regions based on some of the plurality of memory cells in the nonvolatile memory in accordance with an address translation table holding mapping information that indicates a correspondence between physical addresses specifying the data storage regions and logical addresses; and

performing, with a predetermined probability at each time of the access, a wear-leveling process that levels wearout of the plurality of memory cells that is caused by the access,

the performing of the wear-leveling process includes performing, with a first probability at each time of the access, a table update process that updates the mapping information in the address translation table.

(19)

The wear-leveling processing method according to (18), in which the performing of the wear-leveling process includes performing, in a case where the access is write access, a data inversion process that inverts bits in write data to be written to the memory cells with a second probability at each time of the write access, the write access in which data is written to some memory cells, corresponding to the data storage region, of the memory cells.

(20)

The wear-leveling processing method according to (18) or (19), in which

the nonvolatile memory includes a cross-point resistive RAM, and

the performing of the wear-leveling process includes performing a resistance state changing process with a third probability at each time of the access to the data storage region, the resistance state changing process in which, among variable resistor elements reversibly changeable between a low resistance state and a high resistance state of some memory cells, corresponding to the data storage region as a target of the access, of the memory cells, the variable resistor elements in the low resistance state are changed to the high resistance state.

### REFERENCE SIGNS LIST

1: semiconductor storage device
10: controller
110: access control unit
120: ECC processor
122: ECC encoder
124: ECC decoder
130: wear-leveling processor
132: address remapping unit
134: data inversion unit
136: refresh unit
138: random number generator
20: nonvolatile memory (nonvolatile memory package)
210: address translation table
220: user data
240: spare data
30: work memory
310: working address translation table
40: host interface, host interface unit
B: bank
D: die
T: tile

1. A controller that controls an operation of a semiconductor storage device including a writable nonvolatile memory, the controller comprising:
an access control unit that controls access to data storage regions based on some of a plurality of memory cells in the nonvolatile memory in accordance with an address translation table holding mapping information that indicates a correspondence between physical addresses specifying the data storage regions and logical addresses; and
a wear-leveling processor that performs a wear-leveling process that levels wearout of the plurality of memory cells that is caused by the access,
the wear-leveling processor performing the wear-leveling process with a predetermined probability at each time of the access.

2. The controller according to claim 1, wherein the wear-leveling processor includes a table update unit that performs a table update process with a first probability at each time of the access, the table update process that updates the mapping information in the address translation table.

3. The controller according to claim 2, wherein the table update unit replaces one physical address, corresponding to one logical address of the logical addresses, of the physical addresses with another physical address, the one logical address specifying the data storage region as a target of the access, and the other physical address being different from the one physical address and randomly selected.

4. The controller according to claim 3, wherein the table update unit replaces data stored in the data storage region specified by the other physical address with data stored in the data storage region specified by the one physical address.

5. The controller according to claim 2, comprising a random number generator that generates a random number, wherein
the table update unit determines whether or not to perform the table update process on a basis of a random number generated by the random number generator at each time of the access.

6. The controller according to claim 2, wherein
the address translation table holds the mapping information for each storage region that stores a predetermined number of the data storage regions, and
the table update unit performs the table update process for each of the storage regions that store the data storage region as a target of the access.

7. The controller according to claim 6, wherein the table update unit performs the table update process for every several data storage regions of the data storage regions in the storage region.

8. The controller according to claim 7, wherein the table update unit performs the table update process on each of the several data storage regions of the data storage regions in the storage region.

9. The controller according to claim 2, wherein
the access controlled by the access control unit includes write access and readout access, the write access in which data is written to some memory cells, corresponding to the data storage region, of the memory cells, and the readout access in which data is read out from some memory cells, corresponding to the data storage region, of the memory cells, and
a value of the first probability that the table update unit performs the table update process differs depending on whether the access is the write access or the readout access.

10. The controller according to claim 1, wherein the wear-leveling processor includes a data inversion processor that performs, in a case where the access controlled by the access control unit is write access, a data inversion process that inverts bits in write data to be written to the memory cells with a second probability at each time of the write access, the write access in which data is written to some memory cells, corresponding to the data storage region, of the memory cells.

11. The controller according to claim 10, wherein the data inversion processor adds, to the write data, data inversion information that indicates whether or not the data inversion process has been performed at the time of the write access.

12. The controller according to claim 1, wherein
the nonvolatile memory comprises a cross-point resistive RAM,
a plurality of the memory cells each includes a variable resistor element that is reversibly changeable between a low resistance state and a high resistance state, and
the wear-leveling processor includes a resistance state changing unit that performs a resistance state changing process with a third probability at each time of the access to the data storage region, the resistance state changing process that changes, to the high resistance state, the variable resistor elements in the low resistance state among the variable resistor elements of some memory cells, corresponding to the data storage region as a target of the access, of the memory cells.

13. The controller according to claim 12, wherein
the resistance state changing unit issues a resistance state changing command for executing the resistance state changing process to the nonvolatile memory including the data storage region as the target of the access to execute the resistance state changing process, and
the resistance state changing command is a command different from a write command and a readout command, the write command being issued by the access control unit at a time of write access in which data is written to some memory cells, corresponding to the data storage region as the target of the access, of the memory cells, and the readout command being issued by the access control unit at a time of readout access in which data is read out from some memory cells, corresponding to the data storage region as the target of the access, of the memory cells.

14. A semiconductor storage device provided with a nonvolatile memory and a controller, the nonvolatile memory including a plurality of writable nonvolatile memory cells, the controller that controls the nonvolatile memory, the controller comprising:
an access control unit that controls access to data storage regions based on some of a plurality of memory cells in the nonvolatile memory in accordance with an address translation table holding mapping information that indicates a correspondence between physical addresses specifying the data storage regions and logical addresses; and
a wear-leveling processor that performs a wear-leveling process that levels wearout of the plurality of memory cells that is caused by the access,
the wear-leveling processor performing the wear-leveling process with a predetermined probability at each time of the access.

15. The semiconductor storage device according to claim 14, wherein the wear-leveling processor includes a table update unit that performs a table update process with a first probability at each time of the access, the table update process that updates the mapping information in the address translation table.

16. The semiconductor storage device according to claim 14, wherein the wear-leveling processor includes a data inversion processor that performs, in a case where the access controlled by the access control unit is write access, a data inversion process that inverts bits in write data to be written to the memory cells with a second probability at each time of the write access, the write access in which data is written to some memory cells, corresponding to the data storage region, of the memory cells.

17. The semiconductor storage device according to claim 14, wherein
the nonvolatile memory comprises a cross-point resistive RAM,
the plurality of memory cells each includes a variable resistor element that is reversibly changeable between a low resistance state and a high resistance state, and
the wear-leveling processor includes a resistance state changing unit that performs a resistance state changing process with a third probability at each time of the access to the data storage region, the resistance state changing process that changes, to the high resistance state, the variable resistor elements in the low resistance state among the variable resistor elements of some memory cells, corresponding to the data storage region as a target of the access, of the memory cells.

18. A wear-leveling processing method in which in a semiconductor storage device including a nonvolatile memory that includes a plurality of writable nonvolatile memory cells, wearout of the plurality of memory cells is leveled, the wear-leveling processing method comprising:
controlling access to data storage regions based on some of the plurality of memory cells in the nonvolatile memory in accordance with an address translation table holding mapping information that indicates a correspondence between physical addresses specifying the data storage regions and logical addresses; and
performing, with a predetermined probability at each time of the access, a wear-leveling process that levels wearout of the plurality of memory cells that is caused by the access,
the performing of the wear-leveling process includes performing, with a first probability at each time of the access, a table update process that updates the mapping information in the address translation table.

19. The wear-leveling processing method according to claim 18, wherein the performing of the wear-leveling process includes performing, in a case where the access is write access, a data inversion process that inverts bits in write data to be written to the memory cells with a second probability at each time of the write access, the write access in which data is written to some memory cells, corresponding to the data storage region, of the memory cells.

20. The wear-leveling processing method according to claim 18, wherein
the nonvolatile memory comprises a cross-point resistive RAM, and
the performing of the wear-leveling process includes performing a resistance state changing process with a third probability at each time of the access to the data storage region, the resistance state changing process in which, among variable resistor elements reversibly changeable between a low resistance state and a high resistance state of some memory cells, corresponding to the data storage region as a target of the access, of the memory cells, the variable resistor elements in the low resistance state are changed to the high resistance state.
